(19) United States
(12) Patent Application Publication
(10) Pub. No.: US 2026/0047284 A1
(43) Pub. Date: Feb. 12, 2026

(54) DISPLAY DEVICE AND ELECTRONIC DEVICE INCLUDING DISPLAY DEVICE

(71) Applicant: Samsung Display Co., LTD., Yongin-si (KR)

(72) Inventors: Soo Chul KIM, Yongin-si (KR); Ki Bum KIM, Yongin-si (KR); Dae Hyun KIM, Yongin-si (KR); Buem Joon KIM, Yongin-si (KR); Tae Gyun KIM, Yongin-si (KR); Young Chul SIM, Yongin-si (KR); So Young LEE, Yongin-si (KR); Won Ho LEE, Yongin-si (KR); Sang Hyung LIM, Yongin-si (KR)

(21) Appl. No.: 19/257,300

(22) Filed: Jul. 1, 2025

(30) Foreign Application Priority Data
Aug. 12, 2024 (KR) 10-2024-0107839

(51) Int. Cl. H10K 59/123; H10H 29/39; H10H 29/80; H10K 59/80; H10K 102/00; H10K 102/10

(52) U.S. Cl. CPC H10K 59/123; H10H 29/39; H10H 29/8323; H10H 29/8325; H10K 59/80518; H10K 2102/103; H10K 2102/341

(57) ABSTRACT

A display device includes a pixel circuit layer, a first light-emitting-element layer, a second light-emitting-element layer, and a third light-emitting-element layer. The pixel circuit layer includes a pixel circuit. The first light-emitting-element layer is disposed on the pixel circuit layer, and includes a first light emitting element and first conductive patterns spaced apart from the first light emitting element. The second light-emitting-element layer is disposed on the first light-emitting-element layer, and includes a second light emitting element spaced apart from the first light emitting element, and second conductive patterns connected to the first conductive patterns. The third light-emitting-element layer is disposed on the second light-emitting-element layer, and includes a third light emitting element spaced apart from the first light emitting element and the second light emitting element, and third conductive patterns connected to the second conductive patterns.

This application claims priority to Korean Patent Application No. 10-2024-0107839, filed on Aug. 12, 2024, and all the benefits accruing therefrom under 35 U.S.C. § 119, the content of which in its entirety is herein incorporated by reference.

### BACKGROUND

### (1) Field

Various embodiments of the disclosure relate to a display device. Particularly, various embodiments of the disclosure relate to a display device, a method of fabricating the display device, and an electronic device including the display device.

### (2) Description of the Related Art

Recently, as interest in information display increases, research and development on display devices have been continuously conducted.

### SUMMARY

Various embodiments of the disclosure are directed to a display device with improved reliability and enhanced light output efficiency.

A display device in accordance with embodiments of the disclosure includes: a pixel circuit layer including a pixel circuit; a first light-emitting-element layer disposed on the pixel circuit layer, where the first light-emitting-element layer includes a first light emitting element which generates light of a first color, and first conductive patterns spaced apart from the first light emitting element in a plan view; a second light-emitting-element layer disposed on the first light-emitting-element layer, where the second light-emitting-element layer includes a second light emitting element which generates light of a second color different from the first color and is spaced apart from the first light emitting element in the plan view, and second conductive patterns connected to the first conductive patterns; and a third light-emitting-element layer disposed on the second light-emitting-element layer, where the third light-emitting-element layer includes a third light emitting element which generates light of a third color different from the first color and the second color and is spaced apart from the first light emitting element and the second light emitting element in the plan view, and third conductive patterns connected to the second conductive patterns.

In an embodiment, each of the first conductive patterns may be disposed between the first to the third light emitting elements without overlapping the first to the third light emitting elements in the plan view. In such an embodiment, the second conductive patterns may respectively overlap the first conductive patterns in the plan view. In such an embodiment, the third conductive patterns may respectively overlap the second conductive patterns in the plan view.

In an embodiment, each of the first to the third conductive patterns may include: a connection electrode; and a reflective electrode covering at least a portion of the connection electrode.

In an embodiment, the reflective electrode may cover a side surface of the connection electrode.

In an embodiment, the connection electrode may include at least one selected from copper and tungsten. In such an embodiment, the reflective electrode may include at least one selected from aluminum and silver.

In an embodiment, the display device may further include: a first conductive layer disposed between the first light-emitting-element layer and the second light-emitting-element layer; a second conductive layer disposed between the second light-emitting-element layer and the third light-emitting-element layer; and a third conductive layer disposed on the third light-emitting-element layer.

In an embodiment, the first conductive layer may contact the first light emitting element, the first conductive patterns, and the second conductive patterns. The second conductive layer may contact the second light emitting element, the second conductive patterns, and the third conductive patterns. In such an embodiment, the third conductive layer may contact the third light emitting element and the third conductive patterns.

In an embodiment, each of the first to the third conductive layers may include indium tin oxide (ITO).

In an embodiment, the display device may further include: a first connection pattern overlapping the second light emitting element, and connecting the pixel circuit layer to the second light emitting element; and a second connection pattern overlapping the third light emitting element, and connecting the pixel circuit layer to the third light emitting element.

In an embodiment, each of the first connection pattern and the second connection pattern may include at least one selected from copper and tungsten.

In an embodiment, the first conductive layer may include: a first bridge pattern overlapping the second light emitting element, and contacting the first connection pattern, and a second bridge pattern overlapping the third light emitting element, and contacting the second connection pattern, where a first opening may be defined in the first conductive layer around the first bridge pattern; and a second opening may be defined in the first conductive layer around the second bridge pattern.

In an embodiment, the second conductive layer may include: a third bridge pattern overlapping the third light emitting element, and contacting the second connection pattern, where a third opening may be defined in the second conductive layer around the third bridge pattern.

In an embodiment, the first light-emitting-element layer may further include first bonding patterns connected to the pixel circuit layer, the first light emitting element, the first connection pattern, and the second connection pattern.

In an embodiment, the second light-emitting-element layer may further include a second bonding pattern connected to the first connection pattern and the second light emitting element.

In an embodiment, the third light-emitting-element layer may further include a third bonding pattern connected to the second connection pattern and the third light emitting element.

In an embodiment, the display device may further include a lens layer disposed on the third light-emitting-element layer, where lens layer may include lenses overlapping respectively the first to the third light emitting elements.

A display device including first to fourth sub-pixel areas in accordance with embodiments of the disclosure includes: a pixel circuit layer including a pixel circuit; first to fourth sub-pixels respectively disposed in the first to fourth sub-pixel areas; a first light-emitting-element layer disposed on the pixel circuit layer, where the first light-emitting-element layer includes a first first light emitting element disposed in the second sub-pixel area, a first second light emitting element disposed in the fourth sub-pixel area, and first conductive patterns disposed between the first to fourth sub-pixel areas; a second light-emitting-element layer disposed on the first light-emitting-element layer, where the second light-emitting-element layer includes a second light emitting element disposed in the third sub-pixel area, and second conductive patterns disposed between the first to fourth sub-pixel areas, and overlapping respectively the first conductive patterns; and a third light-emitting-element layer disposed on the second light-emitting-element layer, where the third light-emitting-element layer includes a third light emitting element disposed in the first sub-pixel area, and third conductive patterns disposed between the first to fourth sub-pixel areas, and overlapping respectively the first and the second conductive patterns.

In an embodiment, the display device may further include: a first conductive layer disposed between the first light-emitting-element layer and the second light-emitting-element layer, and connected to the first first light emitting element, the first second light emitting element, the first conductive patterns, and the second conductive patterns; a second conductive layer disposed between the second light-emitting-element layer and the third light-emitting-element layer, and connected to the second light emitting element, the second conductive patterns, and the third conductive patterns; and a third conductive layer disposed on the third light-emitting-element layer, and connected to the third light emitting element and the third conductive patterns.

In an embodiment, the first light-emitting-element layer may further include a first first connection pattern overlapping the third sub-pixel area. In such an embodiment, the second light-emitting-element layer may further include a first second connection pattern overlapping the third sub-pixel area, and connected to the first first connection pattern and the second light emitting element. In such an embodiment, the first first connection pattern and the first second connection pattern may be connected to each other through the first conductive layer.

In an embodiment, the first light-emitting-element layer may further include a second first connection pattern overlapping the first sub-pixel area. In such an embodiment, the second light-emitting-element layer may further include a second second connection pattern overlapping the first sub-pixel area, and connected to the second first connection pattern. In such an embodiment, the third light-emitting-element layer may further include a second third connection pattern overlapping the first sub-pixel area, and connected to the second second connection pattern and the third light emitting element. In such an embodiment, the second first connection pattern and the second second connection pattern may be connected to each other through the first conductive layer. In such an embodiment, the second second connection pattern and the second third connection pattern may be connected to each other through the second conductive layer.

An electronic device in accordance with embodiments of the disclosure includes a processor which provides input image data; and a display device which displays an image based on the input image data, where the display device includes: a pixel circuit layer including a pixel circuit; a first light-emitting-element layer disposed on the pixel circuit layer, where the first light-emitting-element layer includes a first light emitting element which generates light of a first color, and first conductive patterns spaced apart from the first light emitting element in a plan view; a second light-emitting-element layer disposed on the first light-emitting-element layer, where the second light-emitting-element layer includes a second light emitting element which generates light of a second color different from the first color and is spaced apart from the first light emitting element in the plan view, and second conductive patterns connected to the first conductive patterns; and a third light-emitting-element layer disposed on the second light-emitting-element layer, where the third light-emitting-element layer includes a third light emitting element which generates light of a third color different from the first color and the second color and is spaced apart from the first light emitting element and the second light emitting element in the plan view, and third conductive patterns connected to the second conductive patterns.

Details of various embodiments are included in the detailed descriptions and drawings.

### BRIEF DESCRIPTION OF THE DRAWINGS

FIG. 1 is a block diagram illustrating an embodiment of a display device.

FIG. 2 is a block diagram illustrating an embodiment of one of sub-pixels of FIG. 1.

FIG. 3 is a plan view illustrating an embodiment of a display panel of FIG. 1.

FIG. 4 is a sectional view illustrating an embodiment of the display panel of FIG. 3.

FIG. 5 is a sectional view illustrating another embodiment of the display panel of FIG. 3.

FIG. 6 is an enlarged plan view illustrating a portion of a display area of the display panel in FIG. 3.

FIG. 7 is a sectional view taken along line I-I′ of FIG. 6.

FIG. 8 is a sectional view illustrating an enlargement of a first light emitting element of FIG. 7.

FIG. 9 is an enlarged plan view illustrating a portion of a non-display area of the display panel in FIG. 3.

FIG. 10 is a sectional view taken along line II-II′ of FIG. 9.

FIG. 11 is an enlarged plan view illustrating a portion of a pad area of the display panel in FIG. 3.

FIG. 12 is a sectional view taken along line III-III′ of FIG. 11.

FIG. 13 is a sectional view illustrating another embodiment of FIG. 7.

FIG. 14 is a sectional view illustrating another embodiment of FIG. 10.

FIG. 15 is a sectional view illustrating another embodiment of FIG. 12.

FIGS. 16 to 46 are diagrams illustrating a method of fabricating the display device (or the display panel) in accordance with an embodiment of the disclosure.

FIG. 47 is a schematic block diagram illustrating an electronic device 1000 including a display device in accordance with an embodiment.

FIG. 48 is a schematic diagram illustrating an embodiment where the electronic device 1000 of FIG. 47 is a smartphone.

FIG. 49 is a schematic diagram illustrating an embodiment where the electronic device 1000 of FIG. 47 is a tablet computer.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

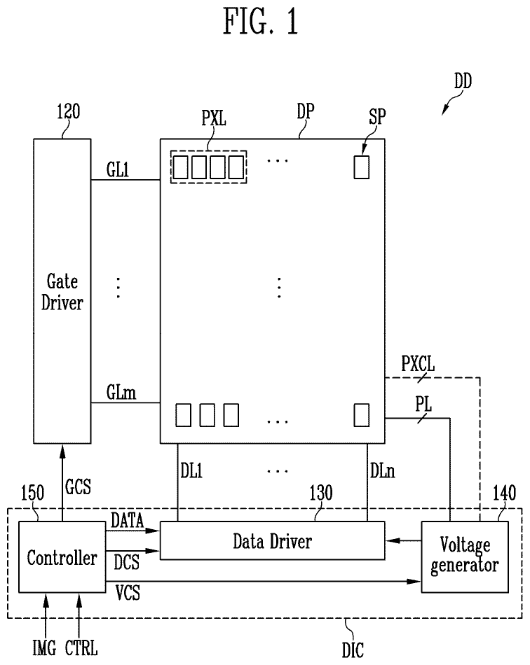

FIG. 1 is a block diagram illustrating an embodiment of a display device DD.

Referring to FIG. 1, an embodiment of the display device DD may include a display panel DP, a gate driver 120, a data driver 130, a voltage generator 140, and a controller 150.

The display panel DP may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn. Here, m and n are natural numbers greater than 1.

The sub-pixels SP may generate light in two or more colors. In an embodiment, for example, each of the sub-pixels SP may generate light in a color such as red, green, blue, cyan, magenta, or yellow.

Two or more sub-pixels among the sub-pixels SP may form or collectively define one pixel PXL. In an embodiment, for example, the pixel PXL may be defined by four sub-pixels, as illustrated in FIG. 1. In such an embodiment, the pixel PXL may emit light of various colors and various luminance levels depending on the combination of light emitted from the sub-pixels included therein.

The gate driver 120 may be connected to the sub-pixels SP arranged in a row direction through the first to m-th gate lines GL1 to GLm. The gate driver 120 may output gate signals to the first to m-th gate lines GL1 to GLm in response to a gate control signal GCS. In an embodiment, the gate control signal GCS may include a start signal instructing each frame to start, a horizontal synchronization signal, and the like.

In an embodiment, for example, the gate driver 120 may be disposed on one side of the display panel DP. However, the embodiments are not limited to the aforementioned example. In another embodiment, for example, the gate driver 120 may be divided into two or more drivers that are physically and/or logically distinguished from each other. The drivers may be disposed on a first side of the display panel DP and a second side of the display panel DP opposite to the first side. In such embodiments, the gate driver 120 may be disposed around the display panel DP in various forms depending on the embodiments.

The data driver 130 may be connected to sub-pixels SP arranged in a column direction through the first to n-th data lines DL1 to DLn. The data driver 130 may receive image data DATA and a data control signal DCS from the controller 150. The data driver 130 may operate in response to the data control signal DCS. In an embodiment, the data control signal DCS may include a source start signal, a source shift clock, a source output enable signal, and the like.

The data driver 130 may receive voltages from the voltage generator 140. The data driver 130 may apply, using received voltages, data signals having grayscale voltages corresponding to the image data DATA to the first to n-th data lines DL1 to DLn. When a gate signal is applied to each of the first to m-th gate lines GL1 to GLm, data signals corresponding to the image data DATA may be applied to the data lines DL1 to DLn. Hence, the sub-pixels SP may generate light corresponding to the data signals, and the display panel DP may display an image.

In an embodiment, the gate driver 120 and the data driver 130 may include complementary metal-oxide semiconductor (CMOS) circuit elements.

The voltage generator 140 may operate in response to a voltage control signal VCS provided from the controller 150. The voltage generator 140 is configured to generate a plurality of voltages and provide the generated voltages to components of the display device DD such as the gate driver 120, the data driver 130, and the controller 150. The voltage generator 140 may receive an input voltage from an external device of the display device DD and generate a plurality of voltages by regulating the received voltage.

The voltage generator 140 may generate a first power voltage and a second power voltage. The generated first and second power voltages may be provided to the sub-pixels SP through power lines PL. In an embodiment, at least one of the first and second power voltages may be provided from an external device to the display device DD.

In addition, the voltage generator 140 may provide various voltages and/or signals. In an embodiment, for example, the voltage generator 140 may provide one or more initialization voltages to be applied to the sub-pixels SP. In an embodiment, for example, during a sensing operation for sensing electrical characteristics of transistors and/or light emitting elements of the sub-pixels SP, a certain reference voltage may be applied to each of the first to n-th data lines DL1 to DLn. The voltage generator 140 may generate the reference voltage and transmit the reference voltage to the data driver 130. In an embodiment, for example, during a display operation for displaying an image on the display panel DP, common pixel control signals may be applied to the sub-pixels SP, and the voltage generator 140 may generate the pixel control signals. In an embodiment, the voltage generator 140 may provide pixel control signals to the sub-pixels SP through pixel control lines PXCL. Although FIG. 1 illustrates an embodiment where the pixel control lines PXCL are connected between the voltage generator 140 and the display panel DP, the embodiments are not limited thereto. In another embodiment, for example, the pixel control lines PXCL may be connected between the gate driver 120 and the display panel DP. In such an embodiment, the pixel control signals may be transmitted from the voltage generator 140 to the pixel control lines PXCL through the gate driver 120.

The controller 150 may control overall operations of the display device DD. The controller 150 may receive input image data IMG and a control signal CTRL corresponding thereto from an external device. The controller 150 may provide a gate control signal GCS, a data control signal DCS, and a voltage control signal VCS, in response to the control signal CTRL.

The controller 150 may convert the input image data IMG to be suitable for the display device DD or the display panel DP and then output image data DATA. In an embodiment, the controller 150 may align the input image data IMG to be suitable for the sub-pixels SP on a row basis and then output the image data DATA.

Two or more components of the data driver 130, the voltage generator 140, and the controller 150 may be mounted on a single integrated circuit. In an embodiment, as illustrated in FIG. 1, the data driver 130, the voltage generator 140, and the controller 150 may be included in a driver integrated circuit DIC. In this case, the data driver 130, the voltage generator 140, and the controller 150 may be components that are functionally separated from each other in the single driver integrated circuit DIC. In an embodiment, at least one selected from the data driver 130, the voltage generator 140, and the controller 150 may be provided as a component separated from the driver integrated circuit DIC.

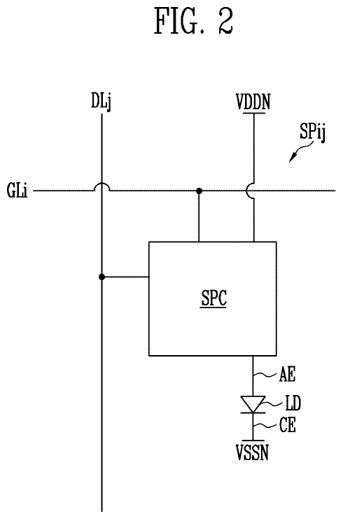

FIG. 2 is a block diagram illustrating an embodiment of one of the sub-pixels SP of FIG. 1. In FIG. 2, a sub-pixel SPij disposed on an i-th row (where i is an integer equal to or greater than 1 and less than or equal to m) and a j-th column (where j is an integer equal to or greater than 1 and less than or equal to n) among the sub-pixels SP of FIG. 1 is illustrated.

Referring to FIG. 2, an embodiment of the sub-pixel SPij may include a sub-pixel circuit SPC and a light emitting element LD.

The light emitting element LD may be connected between a first power voltage node VDDN and a second power voltage node VSSN. The first power voltage node VDDN may be connected to one of the power lines PL of FIG. 1 to receive a first power voltage. The second power voltage node VSSN may be connected to another one of the power lines PL of FIG. 1 to receive a second power voltage. The first power voltage may have a voltage level higher than the second power voltage.

The light emitting element LD may be connected between an anode electrode AE and a cathode electrode CE. The anode electrode AE may be connected to the first power voltage node VDDN through the sub-pixel circuit SPC. In an embodiment, for example, the anode electrode AE may be connected to the first power voltage node VDDN through one or more transistors included in the sub-pixel circuit SPC. The cathode electrode CE may be connected to the second power voltage node VSSN. The light emitting element LD is configured to emit light based on current flowing from the anode electrode AE to the cathode electrode CE.

The sub-pixel circuit SPC may be connected both to an i-gate line GLi among the first to m-th gate lines GL1 to GLm of FIG. 1 and to a j-th data line DLj among the first to n-th data lines DL1 to DLn of FIG. 1. In response to a gate signal received through the i-th gate line GLi, the sub-pixel circuit SPC may control the light emitting element LD to emit light based on a data signal received through the j-th data line DLj. In an embodiment, the sub-pixel circuit SPC may be further connected to the pixel control lines PXCL of FIG. 1. In such an embodiment, the sub-pixel circuit SPC may further control the light emitting element LD in response to pixel control signals received through the pixel control lines PXCL.

To perform the aforementioned operations, the sub-pixel circuit SPC may include pixel circuits, for example, transistors and one or more capacitors.

The transistors of the sub-pixel circuit SPC may include P-type transistors and/or N-type transistors. In an embodiment, the transistors of the sub-pixel circuit SPC may include a metal oxide silicon field effect transistor (MOSFET). In an embodiment, the transistors of the sub-pixel circuit SPC may include an amorphous silicon semiconductor, a monocrystalline silicon semiconductor, a polycrystalline silicon semiconductor, an oxide semiconductor, or the like.

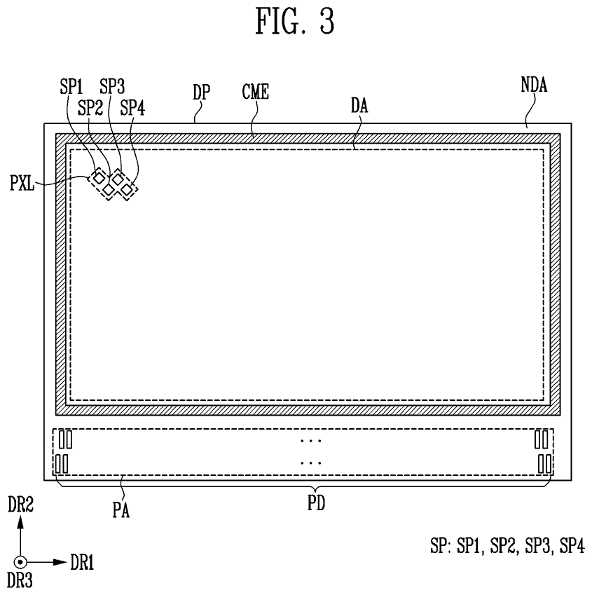

FIG. 3 is a plan view illustrating an embodiment of the display panel DP of FIG. 1.

Referring to FIG. 3, an embodiment of the display panel DP may include a display area DA, a non-display area NDA, and a pad area PA. The display panel DP may display an image through the display area DA. The pad area PA may be spaced apart from the display area DA in a second direction DR2. The non-display area NDA may be disposed around the display area DA.

The display panel DP includes sub-pixels SP in the display area DA. The sub-pixels SP may be arranged in a first direction DR1 and the second direction DR2 intersecting with the first direction DR1 in a plan view or when viewed in a third direction DR3. Here, the third direction DR3 may be a direction perpendicular to the first direction DR1 and the second direction DR2 or a thickness direction of the display panel DP. In an embodiment, for example, the sub-pixels SP may be arranged in the form of a matrix in the first direction DR1 and the second direction DR2. In another embodiment, for example, the sub-pixels SP may be arranged in a zigzag form in the first direction DR1 and the second direction DR2. The arrangement of the sub-pixels SP may be variously modified depending on embodiments. The first direction DR1 may refer to a row direction, and the second direction DR2 may refer to a column direction.

Two or more sub-pixels among the sub-pixels SP may form or collectively define one pixel PXL. Although FIG. 3 illustrates an embodiment where the pixel PXL is defined by four sub-pixels SP1 to SP4, the embodiments are not limited thereto. In another embodiment, for example, the pixel PXL may include two or three sub-pixels. Hereinafter, for convenience of description, embodiments where the pixel PXL is defined by first to four sub-pixels SP1 to SP4 will hereinafter be mainly described.

Each of the first to fourth sub-pixels SP1 to SP4 may generate light of one among various colors such as red, green, blue, cyan, magenta, and yellow. Hereinafter, for convenience of description, embodiments where the first sub-pixel SP1 is configured to generate light in red, each of the second color pixel SP2 and the fourth sub-pixel SP4 is configured to generate light in green, and the third sub-pixel SP3 is configured to generate light in blue will hereinafter be mainly described.

Each of the first to fourth sub-pixels SP1 to SP4 may include at least one light emitting element configured to generate light. In an embodiment, the light emitting elements of the first to fourth sub-pixels SP1 to SP4 may generate light in the same color. In an embodiment, for example, the light emitting elements of the first to fourth sub-pixels SP1 to SP4 may generate light in blue. In an embodiment, the light emitting elements of the first to fourth sub-pixels SP1 to SP4 may generate light in different colors. In an embodiment, for example, the light emitting elements of the first to fourth sub-pixels SP1 to SP4 may respectively generate light in red, green, blue, and green.

As a display panel DP, a self-emissive display panel such as an LED display panel using a micro-scale or nano-scale light emitting diode as a light emitting element, and an organic light emitting display panel (OLED panel) using an organic light emitting diode as a light emitting element may be used.

Components for controlling the sub-pixels SP and transmitting signals from pads PD may be disposed in the non-display area NDA. A common electrode CME, which is included in the power lines PL of FIG. 1 and configured to supply the second power voltage VSSN of FIG. 2, and signal lines that are respectively connected to the first to m-th gate lines GL1 to GLm and the first and n-th data lines DL1 to DLn of FIG. 1 may be disposed in the non-display area NDA.

The common electrode CME may receive the second power voltage VSSN from some (e.g., at least one) of the pads PD and supply the second power voltage VSSN to an N-type semiconductor layer of the light emitting element. Some of the pads PD, other than the pads PD that are provided to transmit the second power voltage VSSN, may supply the first power voltage VDDN to a P-type semiconductor layer of the light emitting element. The light emitting element may emit light due to a difference in voltage between the first power voltage VDDN and the second power voltage VSSN.

At least one selected from the gate driver 120, the data driver 130, the voltage generator 140, and the controller 150 of FIG. 1 may be disposed in the non-display area NDA of the display panel DP. In an embodiment, the gate driver 120 may be disposed in the non-display area NDA. In such an embodiment, the data driver 130, the voltage generator 140, and the controller 150 may be implemented as the driver integrated circuit DIC of FIG. 1, which is separate from the display panel DP. The driver integrated circuit DIC may be connected to the lines disposed in the non-display area NDA through the pads PD. In an embodiment, the gate driver 120 along with the data driver 130, the voltage generator 140, and the controller 150 may be implemented as a single integrated circuit that is separate from the display panel DP.

The pads PD, which are respectively connected to the lines disposed in the non-display area NDA (e.g., the common electrode CME and the signal lines) may be disposed in the pad area PA. The pads PD may be connected to the driver integrated circuit DIC.

In an embodiment, the display area DA may have one of various shapes in a plan view. The display area DA may have a closed-loop shape, including linear and/or curved sides. In an embodiment, for example, the display area DA may have one of various shapes, such as a polygon, a circle, a semicircle, and an ellipse, in a plan view.

In an embodiment, the display panel DP may have a planar display surface. In an embodiment, the display panel DP may have a display surface that is at least partially rounded. In an embodiment, the display panel DP may be bendable, foldable, or rollable. In such an embodiment, the display panel DP and/or a substrate of the display panel DP may include materials having flexible properties.

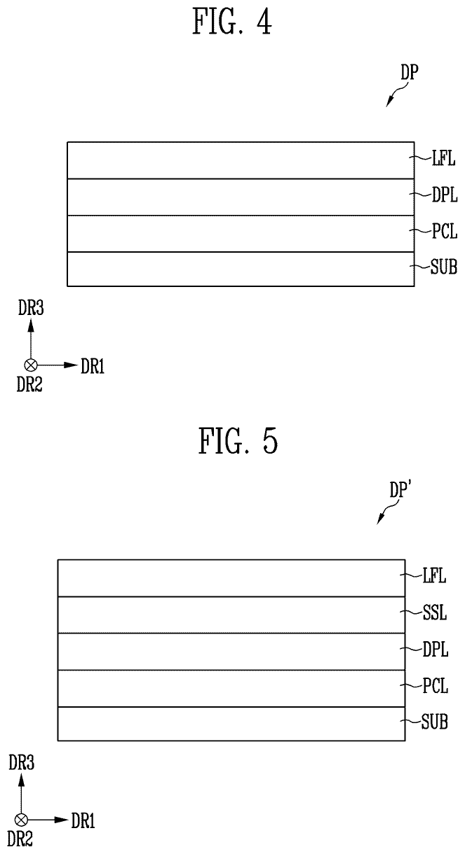

FIG. 4 is a sectional view illustrating an embodiment of the display panel DP of FIG. 3.

Referring to FIG. 4, an embodiment of the display panel DP may include a substrate SUB, and a pixel circuit layer PCL, a display element layer DPL, and a light functional layer (or a light conversion layer) LFL that are sequentially stacked on the substrate SUB in a thickness direction of the substrate SUB or the third direction DR3 intersecting with the first and second directions DR1 and DR2.

The substrate SUB may include or be made of insulating material such as glass or resin. In an embodiment, for example, the substrate SUB may include a glass substrate. In another embodiment, for example, the substrate SUB may include a polyimide (PI) substrate. In another embodiment, for example, the substrate SUB may include a silicon wafer substrate formed through a semiconductor process.

In an embodiment, the substrate SUB may include or be made of material having flexibility to be bendable or foldable, and may have a single-layer structure or a multilayer structure. In an embodiment, for example, the material having flexibility may include at least one selected from the following: polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, the embodiments are not limited thereto.

The pixel circuit layer PCL may be disposed on the substrate SUB. The pixel circuit layer PCL may include insulating layers, and semiconductor electrodes and conductive electrodes disposed between the insulating layers. The conductive electrodes of the pixel circuit layer PCL may function as circuit elements, lines, or the like.

The circuit elements of the pixel circuit layer PCL may include the respective sub-pixel circuits SPC (refer to FIG. 2) of the sub-pixels SP of FIG. 3. In other words, the circuit elements of the pixel circuit layer PCL may be provided as transistors and one or more capacitors of the sub-pixel circuit SPC.

The lines of the pixel circuit layer PCL may include lines connected to the sub-pixels SP. The lines of the pixel circuit layer PCL may include various signal lines and/or voltage lines needed to drive the display element layer DPL.

The display element layer DPL may be disposed on the pixel circuit layer PCL. The display element layer DPL may include light emitting elements of the sub-pixels SP.

The light functional layer LFL may be disposed on the display element layer DPL. The light functional layer LFL may include light conversion patterns having color conversion particles and/or scattering particles. In an embodiment, for example, the color conversion particles may include quantum dots. The quantum dots may convert the wavelength (or color) of light emitted from the display element layer DPL. The light functional layer LFL may further include light scattering patterns having scattering particles. In an embodiment, the light conversion patterns and the light scattering patterns may be omitted.

The light functional layer LFL may further include a color filter layer including color filters. Each of the color filters may selectively transmit light of a specific wavelength (or specific color). In an embodiment, the color filter layer may be omitted.

A window may be provided on the light functional layer LFL to protect an exposed surface (or upper surface) of the display panel DP. The window may protect the display panel DP from an external impact. The window may be connected to the light functional layer LFL by an optically transparent adhesive (or bonding) agent. The window may have a multilayer structure selected from among a glass substrate, a plastic film, and a plastic substrate. The multilayer structure may be formed through a successive process or an adhesion process using an adhesive layer. The entirety or portion of the window may have flexibility.

FIG. 5 is a sectional view illustrating another embodiment of the display panel of FIG. 3.

Referring to FIG. 5, an embodiment of a display panel DP′ may include a substrate SUB, a pixel circuit layer PCL, a display element layer DPL, an input sensing layer SSL, and a light functional layer LFL. The substrate SUB, the pixel circuit layer PCL, the display element layer DPL, and the light functional layer LFL may be substantially the same as the substrate SUB, the pixel circuit layer PCL, the display element layer DPL, and the light functional layer LFL described above with reference to FIG. 4, and any repetitive detailed description thereof will be omitted.

In an embodiment, the input sensing layer SSL may sense a user input on an upper surface (or display surface) of the display panel DP'. The input sensing layer SSL may include components suitable for sensing an external object such as the hand of the user, a pen, or the like. In an embodiment, for example, the input sensing layer SSL may include touch electrodes.

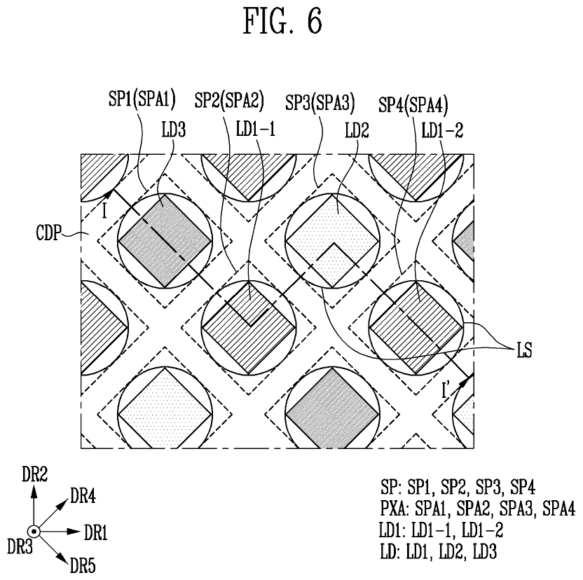

FIG. 6 is an enlarged plan view illustrating a portion of the display area DA of the display panel DP in FIG. 3.

Referring to FIG. 6, an embodiment of the display panel DP includes sub-pixels SP in the display area DA. In an embodiment, the sub-pixels SP may be arranged in a zigzag PENTILE™ structure both in a fourth direction DR4 between the first direction DR1 and the second direction DR2 and in a fifth direction DR5 perpendicular to the fourth direction DR4.

The sub-pixels SP may include first to fourth sub-pixels SP1, SP2, SP3, and SP4. The first to fourth sub-pixels SP1, SP2, SP3, and SP4 may be respectively disposed in first to fourth sub-pixel areas SPA1, SPA2, SPA3, and SPA4.

Light emitting elements LD may be respectively disposed in the first to fourth sub-pixel areas SPA1, SPA2, SPA3, and SPA4. Specifically, a third light emitting element LD3 may be disposed in the first sub-pixel area SPA1, a first first light emitting element (hereinafter, will be referred to as “1-1-th light emitting element”) LD1-1 may be disposed in the second sub-pixel area SPA2, a second light emitting element LD2 may be disposed in the third sub-pixel area SPA3, and a first second light emitting element (hereinafter, will be referred to as “1-2-th light emitting element”) LD1-2 may be disposed in the fourth sub-pixel area SPA4. Each of the 1-1-th light emitting element LD1-1 and the 1-2-th light emitting element LD1-2 may generate light in green, the second light emitting element LD2 may generate light in blue, and the third light emitting element DL3 may generate light in red. However, the disclosure is not limited to the aforementioned example.

In an embodiment, the first to third light emitting elements LD1, LD2, and LD3 may be spaced apart from each other in a plan view or when viewed in the third direction DR3. In other words, the first to third light emitting elements LD1, LD2, and LD3 may not overlap each other in the third direction DR3.

In an embodiment, conductive patterns CDP may be disposed between the first to third light emitting elements LD1, LD2, and LD3. The conductive patterns CDP may be disposed between the first to third light emitting elements LD1, LD2, and LD3 without overlapping the first to third light emitting elements LD1, LD2, and LD3 in a plan view. In an embodiment, the conductive patterns CDP may enclose the first to fourth sub-pixel areas SPA1, SPA2, SPA3, and SPA4 without overlapping the first to fourth sub-pixel areas SPA1, SPA2, SPA3, and SPA4 in a plan view. In other words, the conductive patterns CDP may be disposed between adjacent sub-pixel areas among the first to fourth sub-pixel areas SPA1, SPA2, SPA3, and SPA4.

The conductive patterns CDP may have a mesh structure. The conductive patterns CDP may extend in the fourth direction DR4 or the fifth direction DR5, and may intersect with each other. The conductive patterns CDP may be disposed in an overall area of the display panel DP of FIG. 3 to transmit various signals including voltages.

Lenses LS may be respectively disposed on the first to third light emitting elements LD1, LD2, and LD3. Each of the lenses LS may condense light generated from the corresponding light emitting element LD to improve directivity of light, thereby improving the luminance.

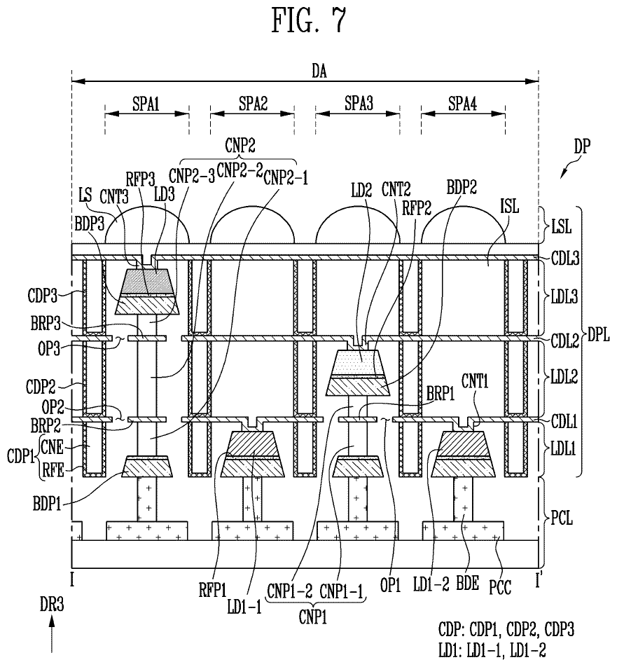

FIG. 7 is a sectional view taken along line I-I′ of FIG. 6. Particularly, FIG. 7 is a sectional view illustrating only the pixel circuit layer PCL and the display element layer DPL of the display panel DP corresponding to one pixel PXL.

Referring to FIG. 7, in an embodiment, the pixel circuit layer PCL may include pixel circuits PCC and bonding electrodes BDE, which correspond to the sub-pixel circuits SPC of FIG. 2.

In the display area DA, the pixel circuits PCC may be respectively disposed in the first to fourth sub-pixel areas SPA1, SPA2, SPA3, and SPA4, and may be spaced apart from each other. The bonding electrodes BDE may respectively electrically connect the pixel circuits PCC to the display element layer DPL. In other words, since the pixel circuits PCC spaced apart from each other in the display area DA may be insulated from each other, different voltages may be respectively transmitted to the display element layer DPL through the bonding electrodes BDE.

The display element layer DPL may be disposed on the pixel circuit layer PCL. The display element layer DPL may include a first light-emitting-element layer LDL1, a first conductive layer CDL1, a second light-emitting-element layer LDL2, a second conductive layer CDL2, a third light-emitting-element layer LDL3, a third conductive layer CDL3, an insulating layer ISL, and a lens layer LSL. Furthermore, the conductive patterns CDP of FIG. 6 may include first conductive patterns CDP1, second conductive patterns CDP2, and third conductive patterns CDP3.

The first light-emitting-element layer LDL1 may be disposed on the pixel circuit layer PCL. The first light-emitting-element layer LDL1 may be disposed on the bonding electrodes BDE, and may be connected to the pixel circuits PCC through the bonding electrodes BDE, respectively.

The first light-emitting-element layer LDL1 may include first bonding patterns BDP1, first reflective patterns RFP1, at least one first light emitting element LD1, first conductive patterns CDP1, a first first connection pattern (hereinafter, will be referred to as “1-1-th connection pattern”) CNP1-1, and a second first connection pattern (hereinafter, will be referred to as “2-1-th connection pattern) CNP2-1.

Each of the first bonding patterns BDP1 may be connected to a corresponding one of the bonding electrodes BDE, the first light emitting element LD1, the 1-1-th connection pattern CNP1-1, and the 2-1-th connection pattern CNP2-1. The first bonding patterns BDP1 may be respectively disposed in the first to fourth sub-pixel areas SPA1, SPA2, SPA3, and SPA4. Each of the first bonding patterns BDP1 may have a double-layer structure including titanium.

The first reflective patterns RFP1 may be respectively disposed on the first bonding patterns BDP1. The first reflective patterns RFP1 may respectively overlap the first bonding patterns BDP1. The first reflective patterns RFP1 may include or be formed of a metal with a higher reflectivity than the first bonding patterns BDP1. In an embodiment, for example, each of the first reflective patterns RFP1 may include aluminum.

The first light-emitting-element layer LDL1 may include at least one first light emitting element LD1. Hereinafter, the structure of the first light emitting element LD1 will be described.

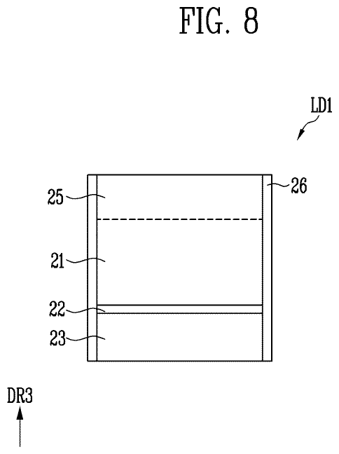

FIG. 8 is a sectional view illustrating an enlargement of the first light emitting element LD1 of FIG. 7.

Referring to FIG. 8, an embodiment of the first light emitting element LD1 may include a first semiconductor layer 21, an active layer 22, a second semiconductor layer 23, and an auxiliary layer 25. The first light emitting element LD1 may be implemented as a vertical emission stack in which the second semiconductor layer 23, the active layer 22, the first semiconductor layer 21, and the auxiliary layer 25 are sequentially stacked in the third direction DR3.

The first semiconductor layer 21 may provide electrons. The first semiconductor layer 21 may include, for example, at least one N-type semiconductor layer. In an embodiment, for example, the first semiconductor layer 21 may include at least one semiconductor material selected from gallium nitride (GaN), aluminum gallium nitride (AlGaN), indium gallium nitride (InGaN), aluminum nitride (AlN), and indium nitride (InN), and may be an N-type semiconductor layer doped with a first conductive dopant (or N-type dopant) such as silicon (Si), germanium (Ge), or tin (Sn). However, the material for forming the first semiconductor layer 21 is not limited to the aforementioned example, and various other materials may be used to form the first semiconductor layer 21. In an embodiment of the disclosure, the first semiconductor layer 21 may include gallium nitride (GaN) semiconductor material doped with a first conductive dopant (or an N-type dopant). In an embodiment, the first semiconductor layer 21 along with the auxiliary layer 25 may form an N-type semiconductor layer.

The active layer 22 may be disposed on the first semiconductor layer 21, and may be an area where electrons and holes are recombined with each other. As electrons and holes are recombined with each other in the active layer 22, the electrons and holes make a transition to a low energy level, thereby generating light having a corresponding wavelength. The active layer 22 may have a single or multi-quantum well structure. In an embodiment where the active layer 22 is formed to have a multi-quantum well structure, units each including a barrier layer, a stain reinforcing layer, and a well layer may be repeatedly stacked to form the active layer 22. However, embodiments of the active layer 22 are not limited to the aforementioned example.

The second semiconductor layer 23 may be disposed on the active layer 22, and may provide holes to the active layer 22. The second semiconductor layer 23 may include a semiconductor layer of a type different from the first semiconductor layer 21. In an embodiment, for example, the second semiconductor layer 23 may include at least one P-type semiconductor layer. In an embodiment, for example, the second semiconductor layer 23 may include at least one semiconductor material selected from gallium nitride (GaN), aluminum gallium nitride (AlGaN), indium gallium nitride (InGaN), aluminum nitride (AlN), and indium nitride (InN), and may be a P-type semiconductor layer doped with a second conductive dopant (or P-type dopant) such as magnesium (Mg), zinc (Zn), calcium (Ca), strontium (Sr), barium (Ba), or the like. However, the material for forming the second semiconductor layer 23 is not limited to the aforementioned example, and various other materials may be used to form the second semiconductor layer 23. In an embodiment of the disclosure, the second semiconductor layer 23 may include gallium nitride (GaN) semiconductor material doped with a second conductive dopant (or a P-type dopant).

The bonding electrode BDE of FIG. 7 may be electrically connected to the second semiconductor layer 23. The bonding electrode BDE may include eutectic metal.

The auxiliary layer 25 may include undoped gallium nitride (GaN) semiconductor material, and may form an N-type semiconductor layer along with the first semiconductor layer 21.

The first light emitting element LD1 may further include an insulating layer 26 provided to cover an outer circumferential surface of the vertical emission stack. The insulating layer 26 may effectively prevent the active layer 22 from short-circuiting due to contact with other conductive material other than the first and second semiconductor layers 21 and 23. The insulating layer 26 may include transparent insulating material. Furthermore, the insulating layer 26 may be configured to expose an upper surface of the auxiliary layer 25 to be in contact the first conductive layer CDL1.

The second light emitting element LD2 and the third light emitting element LD3 may also have a substantially same structure as the first light emitting element LD1.

The disclosure is not limited to the aforementioned example. In an embodiment, the first light emitting element LD1 may have a structure in which the structure of FIG. 8 is reversed in the third direction DR3 (e.g., a structure in which the first semiconductor layer 21 is disposed in a lower portion while the second semiconductor layer 23 is disposed in an upper portion).

Referring back to FIG. 7, the first light-emitting-element layer LDL1 may include the 1-1-th light emitting element LD1-1, and the 1-2-th light emitting element LD1-2.

The 1-1-th light emitting element LD1-1 and the 1-2-th light emitting element LD1-2 may be disposed on corresponding first reflective patterns RFP1 among the first reflective patterns RFP1. The 1-1-th light emitting element LD1-1 may be disposed on the first reflective pattern RFP1 overlapping the second sub-pixel area SPA2. The 1-2-th light emitting element LD1-2 may be disposed on the first reflective pattern RFP1 overlapping the fourth sub-pixel area SPA4. However, the disclosure is not limited to the aforementioned example.

The first reflective patterns RFP1 that are respectively disposed under the 1-1-th light emitting element LD1-1 and the 1-2-th light emitting element LD1-2 may reflect light generated from the 1-1-th light emitting element LD1-1 and the 1-2-th light emitting element LD1-2 such that the light is emitted through the display surface of the display panel DP.

The 1-1-th light emitting element LD1-1 and the 1-2-th light emitting element LD1-2 may generate light of a same color. In an embodiment, for example, the 1-1-th light emitting element LD1-1 and the 1-2-th light emitting element LD1-2 may generate green light. As the first light-emitting-element layer LDL1 is disposed at the lowest position based on the upper surface of the display panel DP, the first light emitting element LD1 configured to generate green light with highest luminance may be disposed in the first light-emitting-element layer LDL1. Furthermore, since the first light-emitting-element layer LDL1 is disposed at the lowest position based on the upper surface of the display panel DP, two first light emitting elements LD1-1 and LD1-2 may be disposed in the first light-emitting-element layer LDL1 corresponding to one pixel PXL. However, the disclosure is not limited to the aforementioned example.

The bonding electrodes BDE that respectively overlap the 1-1-th light emitting element LD1-1 and the 1-2-th light emitting element LD1-2 may receive the first power voltage VDDN from the pads PD of FIG. 3 and supply the first power voltage VDDN to the P-type semiconductor layer of the first light emitting element LD1.

The first conductive patterns CDP1 may be disposed on the pixel circuit layer PCL. The first conductive patterns CDP1 may be spaced apart from the first light emitting element LD1 in a plan view. Furthermore, the first conductive patterns CDP1 may be spaced apart from the first bonding patterns BDP1 and the first reflective patterns RFP1 in a plan view. The first conductive patterns CDP1 may be disposed between two adjacent sub-pixel areas among the first to fourth sub-pixel areas SPA1, SPA2, SPA3, and SPA4. In other words, the first conductive patterns CDP1 may enclose the first light emitting element LD1 in a plan view. The first conductive patterns CDP1 may overlap the first bonding patterns BDP1, the first reflective patterns RFP1, the 1-1-th light emitting element LD1-1, and the 1-2-th light emitting element LD1-2 in a horizontal direction perpendicular to the third direction DR3.

Each of the first conductive patterns CDP1 may include a connection electrode CNE and a reflective electrode RFE. The connection electrode CNE may connect different electrodes, patterns, and layers to transmit various signals including voltages. The connection electrode CNE may include or be formed of a conductive metal. In an embodiment, for example, the connection electrode CNE may include at least one selected from copper and tungsten.

The reflective electrode RFE may cover at least a portion of the connection electrode CNE. In an embodiment, for example, the reflective electrode RFE may cover a side surface of the connection electrode CNE. In another example, the reflective electrode RFE may cover the side surface and a lower surface of the connection electrode CNE. Accordingly, the reflective electrode RFE may have a structure enclosing the first light emitting element LD1. Therefore, the reflective electrode RFE may reflect light generated from the first light emitting element LD1 on a side surface thereof, thereby enhancing the light output efficiency.

The reflective electrode RFE may include or be formed of a metal with a higher reflectivity than the connection electrode CNE. In an embodiment, for example, the reflective electrode RFE may include at least one of aluminum and silver.

The 1-1-th connection pattern CNP1-1 and the 2-1-th connection pattern CNP2-1 may be respectively disposed on the first reflective patterns RFP1 on which no first light emitting element LD1 is disposed. The 1-1-th connection pattern CNP1-1 may overlap (or be disposed in) the third sub-pixel area SPA3. The 2-1-th connection pattern CNP2-1 may overlap the first sub-pixel area SPA1. In other words, the 1-1-th connection pattern CNP1-1 may be connected to the first bonding pattern BDP1 and the first reflective pattern RFP1 in the third sub-pixel area SPA3. The 2-1-th connection pattern CNP2-1 may be connected to the first bonding pattern BDP1 and the first reflective pattern RFP1 in the first sub-pixel area SPA1. The 1-1-th connection pattern CNP1-1 and the 2-1-th connection pattern CNP2-1 may overlap the first conductive patterns CDP1 in the horizontal direction perpendicular to the third direction DR3.

Each of the 1-1-th connection pattern CNP1-1 and the 2-1-th connection pattern CNP2-1 may include or be formed of a same material as the connection electrode CNE. In an embodiment, for example, each of the 1-1-th connection pattern CNP1-1 and the 2-1-th connection pattern CNP2-1 may include at least one selected from copper and tungsten. However, the disclosure is not limited to the aforementioned example.

Furthermore, each of the 1-1-th connection pattern CNP1-1 and the 2-1-th connection pattern CNP2-1 may further include, on at least one side surface thereof, a same material as the reflective electrode RFE. In an embodiment, for example, each of the 1-1-th connection pattern CNP1-1 and the 2-1-th connection pattern CNP2-1 may have the same structure as each of the first conductive patterns CDP1. The disclosure is not limited to the aforementioned example. In an embodiment, for example, the material that is the same as that of the reflective electrode RFE and is applied to the side surface of each of the 1-1-th connection pattern CNP1-1 and the 2-1-th connection pattern CNP2-1 may be omitted.

The first conductive layer CDL1 may be disposed on the first light emitting element layer LDL1. The first conductive layer CDL1 may contact and be connected to the 1-1-th light emitting element LD1-1, the 1-2-th light emitting element LD1-2, the first conductive patterns CDP1, the 1-1-th connection pattern CNP1-1, and the 2-1-th connection pattern CNP2-1.

The first conductive layer CDL1 may include or be formed of conductive material. In an embodiment, for example, the first conductive layer CDL1 may include indium tin oxide (ITO).

The first conductive layer CDL1 may include a first bridge pattern BRP1, and may be provided with a first opening OP1 defined around the first bridge pattern BRP1. The first opening OP1 may have an annular shape enclosing the first bridge pattern BRP1 in a plan view. In other words, the first bridge pattern BRP1 may be insulated from and not connected to other components of the first conductive layer CDL1 due to the first opening OP1.

The first bridge pattern BRP1 may overlap the third sub-pixel area SPA3 and the second light emitting element LD2. The first bridge pattern BRP1 may be in contact with and connected to the 1-1-th connection pattern CNP1-1. The first bridge pattern BRP1 may cover an overall upper surface of the 1-1-th connection pattern CNP1-1. In other words, a surface area of the first bridge pattern BRP1 may be greater than or the same as that of the upper surface of the 1-1-th connection pattern CNP1-1. In an embodiment, the first bridge pattern BRP1 may effectively prevent the 1-1-th connection pattern CNP1-1 from being exposed by covering the overall upper surface of the 1-1-th connection pattern CNP1-1, such that the 1-1-th connection pattern CNP1-1 may be effectively prevented from corroding, and sufficient contact margin may be ensured for a subsequent connection process with a first second connection pattern (hereinafter, will be referred to as “1-2-th connection pattern”) CNP1-2 to be described later.

In an embodiment, the first bridge pattern BRP1 may be connected to the second light emitting element LD2. The second light emitting element LD2 may be connected to the pixel circuit layer PCL through the first bridge pattern BRP1 and the 1-1-th connection pattern CNP1-1, and may receive a signal from the corresponding pixel circuit PCC.

The first conductive layer CDL1 may include a second bridge pattern BRP2 spaced apart from the first bridge pattern BRP1, and may be provided with a second opening OP2 defined around the second bridge pattern BRP2. The second opening OP2 may have an annular shape enclosing the second bridge pattern BRP2 in a plan view. In other words, the second bridge pattern BRP2 may be insulated from and not connected to other components of the first conductive layer CDL1 due to the second opening OP2.

The second bridge pattern BRP2 may overlap the first sub-pixel area SPA1 and the third light emitting element LD3. The second bridge pattern BRP2 may be in contact with and connected to the 2-1-th connection pattern CNP2-1. The second bridge pattern BRP2 may cover an overall upper surface of the 2-1-th connection pattern CNP2-1. In other words, a surface area of the second bridge pattern BRP2 may be greater than or the same as that of the upper surface of the 2-1-th connection pattern CNP2-1.

In an embodiment, the second bridge pattern BRP2 may be electrically connected to the third light emitting element LD3. The third light emitting element LD3 may be connected to the pixel circuit layer PCL through the second bridge pattern BRP2 and the 2-1-th connection pattern CNP2-1, and may receive a signal from the corresponding pixel circuit PCC.

The first conductive layer CDL1 other than the first bridge pattern BRP1 and the second bridge pattern BRP2 may contact the first light emitting element LD1 and the first conductive patterns CDP1. The first conductive layer CDL1 other than the first bridge pattern BRP1 and the second bridge pattern BRP2 may connect the first light emitting element LD1 and the first conductive patterns CDP1 to transmit a signal therebetween. The first conductive layer CDL1 may contact the first light emitting element LD1 through a first contact hole CNT1. In an embodiment, the first conductive layer CDL1 may receive the second power voltage VSSN from the common electrode CME of FIG. 3, and transmit the second power voltage VSSN to the N-type semiconductor layer of the first light emitting element LD1. Furthermore, the first conductive layer CDL1 may electrically connect the first light-emitting-element layer LDL1 and the second light-emitting-element layer LDL2 through the conductive patterns CDP.

The second light-emitting-element layer LDL2 may be disposed on the first conductive layer CDL1. The second light-emitting-element layer LDL2 may include a second bonding pattern BDP2, a second reflective pattern RFP2, a second light emitting element LD2, second conductive patterns CDP2, a first second connection pattern (hereinafter, will be referred to as “1-2-th connection pattern”) CNP1-2, and a second second connection pattern (hereinafter, will be referred to as “2-2-th connection pattern”) CNP2-2.

The second bonding pattern BDP2 may be connected to the first bridge pattern BRP1, the second light emitting element LD2, and the 1-2-th connection pattern CNP1-2. The second bonding pattern BDP2 may be disposed in the third sub-pixel area SPA3. The second bonding pattern BDP2 may have a double-layer structure including titanium.

The second reflective pattern RFP2 may be disposed on the second bonding pattern BDP2. The second reflective pattern RFP2 may include or be formed of a metal with a higher reflectivity than the second bonding pattern BDP2. In an embodiment, for example, the second reflective pattern RFP2 may include aluminum.

The second light-emitting-element layer LDL2 may include at least one second light emitting element LD2. In an embodiment, for example, the second light-emitting-element layer LDL2 corresponding to one pixel PXL may include one second light emitting element LD2.

The second light emitting element LD2 may overlap (or be disposed in) the third sub-pixel area SPA3. In other words, the second light emitting element LD2 may be disposed at a position spaced apart from the 1-1-th light emitting element LD1-1 and the 1-2-th light emitting element LD1-2 in a plan view. Since the second light emitting element LD2 does not overlap the first light emitting element LD1, the light output efficiency may be further enhanced.

The second light emitting element LD2 may be disposed on the second reflective pattern RFP2. The second light emitting element LD2 may be disposed on the second reflective pattern RFP2 that overlaps the third sub-pixel area SPA3.

The second light emitting element LD2 may generate light of a color different from the color of light generated from the first light emitting element LD1. In an embodiment, for example, the second light emitting element LD2 may generate blue light.

The second conductive patterns CDP2 may be disposed on the pixel circuit layer PCL. The second conductive patterns CDP2 may be spaced apart from the second light emitting element LD2 in a plan view. Furthermore, the second conductive patterns CDP2 may be spaced apart from the second bonding pattern BDP2 and the second reflective pattern RFP2 that overlap the second light emitting element LD2, in a plan view.

The second conductive patterns CDP2 may be disposed between two adjacent sub-pixel areas among the first to fourth sub-pixel areas SPA1, SPA2, SPA3, and SPA4. In other words, the second conductive patterns CDP2 may enclose the second light emitting element LD2. The second conductive patterns CDP2 may respectively overlap the first conductive patterns CDP1. Furthermore, the second conductive patterns CDP2 may contact the first conductive layer CDL1, and may be electrically connected to the first conductive patterns CDP1 through the first conductive layer CDL1.

The second conductive patterns CDP2 may overlap the second bonding pattern BDP2, the second reflective pattern RFP2, and the second light emitting element LD2 in the horizontal direction perpendicular to the third direction DR3.

Each of the second conductive patterns CDP2 may include a connection electrode CNE and a reflective electrode RFE. Each of the second conductive patterns CDP2 may have a same structure as each of the first conductive patterns CDP1. Therefore, the second conductive patterns CDP2 may reflect light generated from the second light emitting element LD2 on side surfaces thereof, thereby enhancing the light output efficiency.

The 1-2-th connection pattern CNP1-2 and the 2-2-th connection pattern CNP2-2 may be respectively disposed on the 1-1-th connection pattern CNP1-1 and the 2-1-th connection pattern CNP2-1. The 1-2-th connection pattern CNP1-2 and the 2-2-th connection pattern CNP2-2 may overlap the 1-1-th connection pattern CNP1-1 and the 2-1-th connection pattern CNP2-1, respectively, and be connected to the 1-1-th connection pattern CNP1-1 and the 2-1-th connection pattern CNP2-1, respectively. The 1-2-th connection pattern CNP1-2 may contact the first bridge pattern BRP1 in the third sub-pixel area SPA3, and may be connected to the 1-1-th connection pattern CNP1-1 and the second light emitting element LD2. The 2-2-th connection pattern CNP2-2 may be connected to the second bridge pattern BRP2 and the 2-1-th connection pattern CNP2-1 in the first sub-pixel area SPA1.

The 1-2-th connection pattern CNP1-2 and the 2-2-th connection pattern CNP2-2 may include or be formed of a same material as the 1-1-th connection pattern CNP1-1 and the 2-1-th connection pattern CNP2-1. In an embodiment, for example, each of the 1-2-th connection pattern CNP1-2 and the 2-2-th connection pattern CNP2-2 may include at least one selected from copper and tungsten. However, the disclosure is not limited to the aforementioned example.

In an embodiment, each of the 1-2-th connection pattern CNP1-2 and the 2-2-th connection pattern CNP2-2 may further include, on at least one side surface thereof, a same material as the reflective electrode RFE. In an embodiment, for example, each of the 1-2-th connection pattern CNP1-2 and the 2-2-th connection pattern CNP2-2 may have a same structure as each of the second conductive patterns CDP2. The disclosure is not limited to the aforementioned example. In an embodiment, for example, the material that is the same as that of the reflective electrode RFE and is applied to the side surface of each of the 1-2-th connection pattern CNP1-2 and the 2-2-th connection pattern CNP2-2 may be omitted.

The 1-1-th connection pattern CNP1-1 and the 1-2-th connection pattern CNP1-2 may include a same material, each other and may be connected to each other through the first conductive layer CDL1, e.g., the first bridge pattern BRP1. The 1-1-th connection pattern CNP1-1 and the 1-2-th connection pattern CNP1-2 may form (or collectively define) a single first connection pattern CNP1. The first connection pattern CNP1 may overlap the second light emitting element LD2, and may connect the pixel circuit layer PCL and the second light emitting element LD2 to each other. In other words, the first connection pattern CNP1 may transmit a signal from the pixel circuit PCC to the second light emitting element LD2. In an embodiment, the first connection pattern CNP1 that contacts the second light emitting element LD2 may receive the first power voltage VDDN from the pads PD and the pixel circuit layer PCL of FIG. 3 and supply the first power voltage VDDN to the P-type semiconductor layer of the first light emitting element LD1.

The second conductive layer CDL2 may be disposed on the second light emitting element layer LDL2. The second conductive layer CDL2 may be in contact with and connected to the second light emitting element LD2, the second conductive patterns CDP2, and the 2-2-th connection pattern CNP2-2.

The second conductive layer CDL2 may include or be formed of conductive material. In an embodiment, for example, the second conductive layer CDL2 may include indium tin oxide (ITO).

The second conductive layer CDL2 may include a third bridge pattern BRP3, and may be provided with a third opening OP3 defined around the third bridge pattern BRP3. The third opening OP3 may have an annular shape enclosing the third bridge pattern BRP3 in a plan view. In other words, the third bridge pattern BRP3 may be insulated from and not connected to other components of the third conductive layer CDL3 due to the third opening OP3.

The third bridge pattern BRP3 may overlap the first sub-pixel area SPA1 and the third light emitting element LD3. The third bridge pattern BRP3 may be brought into contact with and connected to the 2-2-th connection pattern CNP2-2. The third bridge pattern BRP3 may cover an overall upper surface of the 2-2-th connection pattern CNP2-2. In other words, a surface area of the third bridge pattern BRP3 may be greater than or the same as that of the upper surface of the 2-2-th connection pattern CNP2-2.

In an embodiment, the third bridge pattern BRP3 may be connected to the third light emitting element LD3. The third light emitting element LD3 may be connected to the pixel circuit layer PCL through the third bridge pattern BRP3, the 2-1-th connection pattern CNP2-1, and the 2-2-th connection pattern CNP2-2, and may receive a signal from the corresponding pixel circuit PCC.

The second conductive layer CDL2 other than the third bridge pattern BRP3 may contact the second light emitting element LD2 and the second conductive patterns CDP2. The second conductive layer CDL2 other than the third bridge pattern BRP3 may connect the second light emitting element LD2 and the second conductive patterns CDP2 to each other, and transmit a signal therebetween. The second conductive layer CDL2 may contact the second light emitting element LD2 through a second contact hole CNT2. In an embodiment, the second conductive layer CDL2 may receive the second power voltage VSSN from the common electrode CME of FIG. 3, and transmit the second power voltage VSSN to the N-type semiconductor layer of the second light emitting element LD2. Furthermore, the second conductive layer CDL2 may electrically connect the second light-emitting-element layer LDL2 and the third light-emitting-element layer LDL3 through the conductive patterns CDP.

The third light-emitting-element layer LDL3 may be disposed on the second conductive layer CDL2. The third light-emitting-element layer LDL3 may include a third bonding pattern BDP3, a third reflective pattern RFP3, a third light emitting element LD3, third conductive patterns CDP3, and a second third connection pattern (hereinafter, will be referred to as “2-3-th connection pattern”) CNP2-3.

The third bonding pattern BDP3 may be connected to the third bridge pattern BRP3, the third light emitting element LD3, and the 2-2-th connection pattern CNP2-2. The third bonding pattern BDP3 may be disposed in the first sub-pixel area SPA1. The third bonding pattern BDP3 may have a double-layer structure including titanium.

The third reflective patterns RFP3 may be disposed on the third bonding pattern BDP3. The third reflective pattern RFP3 may include or be formed of a metal with a higher reflectivity than the third bonding pattern BDP3. In an embodiment, for example, the third reflective pattern RFP3 may include aluminum.

The third light-emitting-element layer LDL3 may include at least one third light emitting element LD3. In an embodiment, for example, the third light-emitting-element layer LDL3 may include one third light emitting element LD3.

The third light emitting element LD3 may overlap the first sub-pixel area SPA1. In other words, the third light emitting element LD3 may be disposed at a position spaced apart from all of the 1-1-th light emitting element LD1-1, the 1-2-th light emitting element LD1-2, and the second light emitting element LD2 in a plan view. Since the third light emitting element LD3 overlaps neither the first light emitting element LD1 nor the second light emitting element LD2, the light output efficiency may be further enhanced.

The third light emitting element LD3 may be disposed on the third reflective pattern RFP3. The third light emitting element LD3 may be disposed on the third reflective pattern RFP3 that overlaps the first sub-pixel area SPA1.

The third light emitting element LD3 may generate light of a color different from the colors of light generated from the first light emitting element LD1 and the second light emitting element LD2. In an embodiment, for example, the third light emitting element LD3 may generate red light.

The third conductive patterns CDP3 may be disposed on the pixel circuit layer PCL. The third conductive patterns CDP3 may be spaced apart from the third light emitting element LD3 in a plan view. Furthermore, the third conductive patterns CDP3 may be spaced apart from the third bonding pattern BDP3 and the third reflective pattern RFP3 that overlap the third light emitting element LD3, in a plan view.

The third conductive patterns CDP3 may be disposed between two adjacent sub-pixel areas among the first to fourth sub-pixel areas SPA1, SPA2, SPA3, and SPA4. In other words, the third conductive patterns CDP3 may enclose the third light emitting element LD3 in a plan view. The third conductive patterns CDP3 may respectively overlap the second conductive patterns CDP2. Furthermore, the third conductive patterns CDP3 may contact the second conductive layer CDL2, and may be electrically connected to the second conductive patterns CDP2 through the second conductive layer CDL2.

The third conductive patterns CDP3 may overlap the third bonding pattern BDP3, the third reflective pattern RFP3, and the third light emitting element LD3 in the horizontal direction perpendicular to the third direction DR3.

Each of the third conductive patterns CDP3 may include a connection electrode CNE and a reflective electrode RFE. Each of the third conductive patterns CDP3 may have a same structure as each of the first conductive patterns CDP1. Therefore, the third conductive patterns CDP3 may reflect light generated from the third light emitting element LD3 on side surfaces thereof, thereby enhancing the light output efficiency.

The 2-3-th connection pattern CNP2-3 may be disposed on the 2-2-th connection pattern CNP2-2. The 2-3-th connection pattern CNP2-3 may overlap with and be connected to the 2-1-th connection pattern CNP2-1 and the 2-2-th connection pattern CNP2-2. The 2-3-th connection pattern CNP2-3 may contact the third bridge pattern BRP3 in the first sub-pixel area SPA1, and may be connected to the 2-2-th connection pattern CNP2-2 and the third light emitting element LD3.

The 2-3-th connection pattern CNP2-3 may include or be formed of a same material as the 2-2-th connection pattern CNP2-2. In an embodiment, for example, the 2-3-th connection pattern CNP2-3 may include at least one selected from copper and tungsten. However, the disclosure is not limited to the aforementioned example.

In an embodiment, the 2-3-th connection pattern CNP2-3 may further include a same material as the reflective electrode RFE on at least one side surface thereof. In an embodiment, for example, the 2-3-th connection pattern CNP2-3 may have a same structure as each of the third conductive patterns CDP3. However, the disclosure is not limited to the aforementioned example, and the material that is applied to the side surface of the 2-3-th connection pattern CNP2-3 and is the same as that of the reflective electrode RFE may be omitted.

The 2-2-th connection pattern CNP2-2 and the 2-3-th connection pattern CNP2-3 may include a same material as each other, and may be connected to each other through the second conductive layer CDL2, e.g., the third bridge pattern BRP3. Likewise, the 2-1-th connection pattern CNP2-1 and the 2-2-th connection pattern CNP2-2 may include a same material as each other, and may be connected to each other through the first conductive layer CDL1, e.g., the second bridge pattern BRP2. The 2-1-th connection pattern CNP2-1, the 2-2-th connection pattern CNP2-2, and the 2-3-th connection pattern CNP2-3 may form a single second connection pattern CNP2. The second connection pattern CNP2 may overlap the third light emitting element LD3, and may connect the pixel circuit layer PCL and the third light emitting element LD3 to each other. In other words, the second connection pattern CNP2 may transmit a signal from the pixel circuit PCC to the third light emitting element LD3. In an embodiment, the second connection pattern CNP2 that contacts the third light emitting element LD3 may receive the first power voltage VDDN from the pads PD and the pixel circuit layer PCL of FIG. 3 and supply the first power voltage VDDN to the P-type semiconductor layer of the first light emitting element LD1.

The third conductive layer CDL3 may be disposed on the third light emitting element layer LDL3. The third conductive layer CDL3 may be in contact with and connected to the third light emitting element LD3 and the third conductive patterns CDP3.

The third conductive layer CDL3 may include or be formed of conductive material. In an embodiment, for example, the third conductive layer CDL3 may include indium tin oxide (ITO).

In an embodiment, the third conductive layer CDL3 may have no insulated bridge pattern, and may extend across the entirety of the display panel DP.

The third conductive layer CDL3 may connect the third light emitting element LD3 and the third conductive patterns CDP3 to each other to transmit a signal therebetween. The third conductive layer CDL3 may contact the third light emitting element LD3 through a third contact hole CNT3 defined in the insulating layer ISL to expose contact the third light emitting element LD3. In detail, the third conductive layer CDL3 may receive the second power voltage VSSN from the common electrode CME of FIG. 3, and transmit the second power voltage VSSN to the N-type semiconductor layer of the third light emitting element LD3.

The insulating layer ISL may be disposed in each of spaces between the pixel circuit layer PCL, and the light emitting elements, the electrodes and the patterns of the first to third light-emitting-element layers LDL1, LDL2, and LDL3. In an embodiment, for example, the insulating layer ISL may include oxide.

The insulating layer ISL may be disposed on the third conductive layer CDL3, and the lens layer LSL may be disposed on the insulating layer ISL. The lens layer LSL may include micro lenses LS having light-condensing properties. In an embodiment, the lens layer LSL may include lenses LS that respectively overlap the first to fourth sub-pixel areas SPA1, SPA2, SPA3, and SPA4. In other words, the lenses LS may respectively overlap the 1-1-th light emitting element LD1-1, the 1-2-th light emitting element LD1-2, the second light emitting element LD2, and the third light emitting element LD3.

Each of the lenses LS may have a hemispherical shape. However, embodiments of the disclosure are not limited to the aforementioned example. In an embodiment, the lenses LS may respectively condense light emitted from the underlying first to third light-emitting-element layers LDL3 and incident thereon, thereby improving the directivity of the light. Consequently, the luminance of the display device may be enhanced.

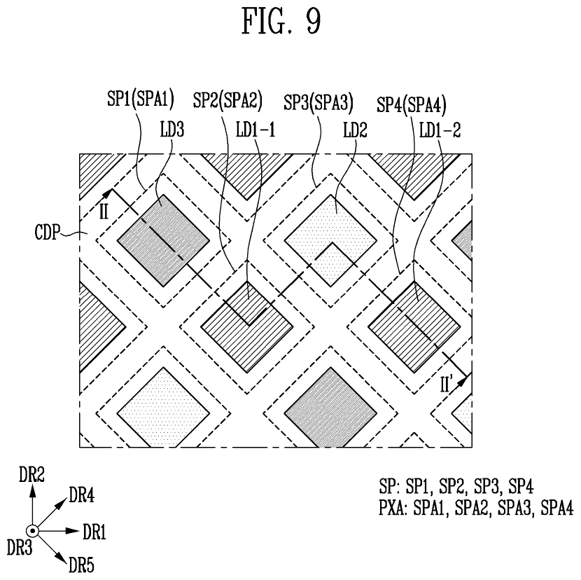

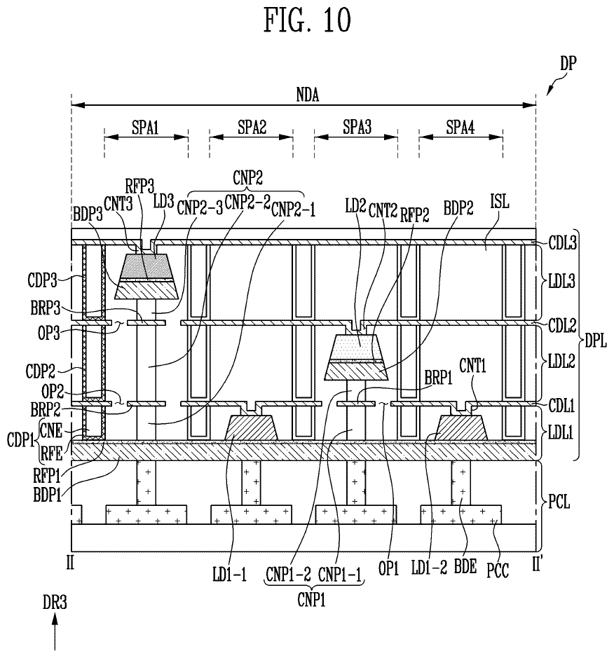

FIG. 9 is an enlarged plan view illustrating a portion of the non-display area NDA of the display panel DP in FIG. 3. FIG. 10 is a sectional view taken along line II-II′ of FIG. 9.

Referring to FIGS. 9 and 10, the non-display area NDA of the display panel DP may have substantially the same configuration as the display area DA of the display panel DP of FIG. 6, except for a pixel circuits PCC, first bonding patterns BDP1, first reflective patterns RFP1, and a lens layer LSL. Accordingly, any repetitive detailed description of the same or like elements as those described above will be omitted or simplified.

The display panel DP may include sub-pixels SP disposed across an entire area including the display area DA, the non-display area NDA, and the pad area PA. As the sub-pixels SP, each including a light emitting element, are disposed throughout the entire area, the density differences of patterns and electrodes between respective areas during a process of fabricating the display panel DP may be minimized, thereby resulting in a uniform level of planarization across the entire area. As a result, uniform quality may be ensured across the entire area of the display device even in a process subsequent to a planarization process.

Accordingly, in such an embodiment, the display panel DP may include sub-pixels SP even in the non-display area NDA. The sub-pixels SP that are disposed in the non-display area NDA may be arranged in the same manner as the sub-pixels SP that are disposed in the display area DA. However, the disclosure is not limited to the aforementioned example, and in another embodiment, the sub-pixels SP may be omitted in the non-display area NDA.

In the non-display area NDA, the pixel circuit PCC included in the pixel circuit layer PCL may be integrally formed in the non-display area NDA. Therefore, the pixel circuit PCC disposed in the non-display area NDA may uniformly transmit a same voltage to the display element layer DPL through the bonding electrodes BDE. In an embodiment, for example, the pixel circuit PCC disposed in the non-display area NDA may include the common electrode CME of FIG. 3. Therefore, the pixel circuit PCC disposed in the non-display area NDA may transmit the second power voltage VSSN to the first to third light-emitting-element layers LDL1, LDL2, and LDL3 and the first to third conductive layers CDL1, CDL2, and CDL3.

The first bonding pattern BDP1 included in the display element layer DPL and the first reflective pattern RFP1 on the first bonding pattern BDP1 may be integrally formed in the non-display area NDA. Therefore, the first bonding pattern BDP1 disposed in the non-display area NDA may be connected to the 1-1-th light emitting element LD1-1, the 1-2-th light emitting element LD1-2, the first conductive patterns CDP1, the first connection pattern CNP1, and the second connection pattern CNP2, and may transmit the same voltage to the 1-1-th light emitting element LD1-1, the 1-2-th light emitting element LD1-2, the first conductive patterns CDP1, the first connection pattern CNP1, and the second connection pattern CNP2.

Accordingly, a same voltage may be transmitted to the N-type semiconductor layer and the P-type semiconductor layer of each of the 1-1-th light emitting element LD1-1, the 1-2-th light emitting element LD1-2, the second light emitting element LD2, and the third light emitting element LD3, such that the 1-1-th light emitting element LD1-1, the 1-2-th light emitting element LD1-2, the second light emitting element LD2, and the third light emitting element LD3 that are disposed in the non-display area NDA may not emit light.

In an embodiment, the first bonding pattern BDP1 and the first reflective pattern RFP1 may transmit the second power voltage VSSN from the pixel circuit PCC to the 1-1-th light emitting element LD1-1, the 1-2-th light emitting element LD1-2, the first conductive patterns CDP1, the first connection pattern CNP1, and the second connection pattern CNP2.

The second power voltage VSSN may be transmitted from the first bonding pattern BDP1 and the first reflective pattern RFP1 to the P-type semiconductor layer of each of the 1-1-th light emitting element LD1-1 and the 1-2-th light emitting element LD1-2. Furthermore, since the first bonding pattern BDP1 and the first reflective pattern RFP1 are connected to the first conductive layer CDL1 through the first conductive patterns CDP1, the second power voltage VSSN may be transmitted from the first conductive layer CDL1 to the N-type semiconductor layer of each of the 1-1-th light emitting element LD1-1 and the 1-2-th light emitting element LD1-2. Therefore, since a same voltage is applied to the N-type semiconductor layer and the P-type semiconductor layer of each of the 1-1-th light emitting element LD1-1 and the 1-2-th light emitting element LD1-2, the 1-1-th light emitting element LD1-1 and the 1-2-th light emitting element LD1-2 may not emit light.

In an embodiment, the first conductive layer CDL1 may extend to the display area DA in a way such that the second power voltage VSSN can be transmitted to the N-type semiconductor layer of each of the 1-1-th light emitting element LD1-1 and the 1-2-th light emitting element LD1-2 of the display area DA.

In such an embodiment, since the first bonding pattern BDP1 and the first reflective pattern RFP1 are connected to the first connection pattern CNP1, the second power voltage VSSN may be transmitted to the P-type semiconductor layer of the second light emitting element LD2 through the first connection pattern CNP1. In addition, since the first conductive layer CDL1 and the second conductive layer CDL2 are connected to each other by the second conductive patterns CDP2, the second power voltage VSSN may be transmitted from the second conductive layer CDL2 to the N-type semiconductor layer of the second light emitting element LD2. Therefore, since a same voltage is applied to the N-type semiconductor layer and the P-type semiconductor layer of the second light emitting element LD2, the second light emitting element LD2 may not emit light.

In an embodiment, the second conductive layer CDL2 may extend to the display area DA in a way such that the second power voltage VSSN can be transmitted to the N-type semiconductor layer of the second light emitting element LD2 of the display area DA.

In such an embodiment, since the first bonding pattern BDP1 and the first reflective pattern RFP1 are connected to the second connection pattern CNP2, the second power voltage VSSN may be transmitted to the P-type semiconductor layer of the third light emitting element LD3 through the second connection pattern CNP2. Furthermore, since the second conductive layer CDL2 and the third conductive layer CDL3 are connected to each other by the third conductive patterns CDP3, the second power voltage VSSN may be transmitted from the third conductive layer CDL3 to the N-type semiconductor layer of the third light emitting element LD3. Therefore, since a same voltage is applied to the N-type semiconductor layer and the P-type semiconductor layer of the third light emitting element LD3, the third light emitting element LD3 may not emit light.

In an embodiment, the third conductive layer CDL3 may extend to the display area DA in a way such that the second power voltage VSSN can be transmitted to the N-type semiconductor layer of the third light emitting element LD3 of the display area DA.

Accordingly, to ensure uniform quality in a fabrication process, a structure may be configured in a way such that light emitting elements LD are arranged in the non-display area NDA, while light is not emitted from the non-display area NDA.

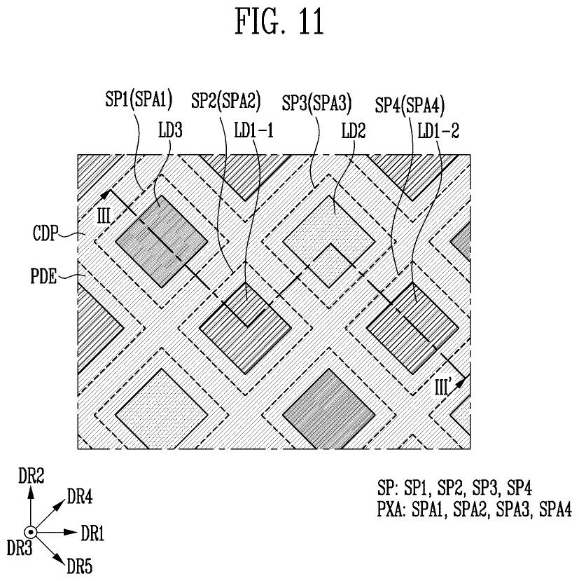

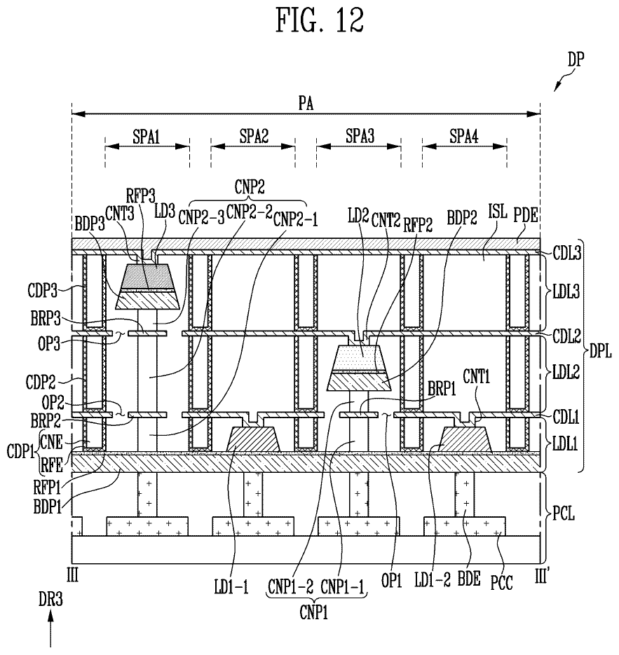

FIG. 11 is an enlarged plan view illustrating a portion of the pad area PA of the display panel DP in FIG. 3. FIG. 12 is a sectional view taken along line III-III′ of FIG. 11.

Referring to FIGS. 11 and 12, the pad area PA of the display panel DP may have substantially the same configuration as the non-display area NDA of the display panel DP of FIGS. 9 and 10 except for a pad electrode PDE. Accordingly, any repetitive detailed description of the same or like elements as those described above will be omitted or simplified.

In an embodiment, the display panel DP may include sub-pixels SP even in the pad area PA. The sub-pixels SP that are disposed in the pad area PA may be arranged in a same manner as the sub-pixels SP that are disposed in the display area DA. However, the disclosure is not limited to the aforementioned example, and in another embodiment, the sub-pixels SP may not be disposed in the pad area PA.

Each of the pads PD of FIG. 3 may include or be formed of a plurality of pad electrodes PDE. The plurality of pad electrodes PDE may be disposed on the third conductive layer CDL3 in the pad area PA. Each of the pad electrodes PDE may have a single-layer or multilayer structure.

The pad electrodes PDE that supply the first power voltage VDDN among the pad electrodes PDE disposed in the pad area PA may transmit the first power voltage VDDN to the display element layer DPL. Therefore, the pad electrodes PDE that supply the first power voltage VDDN among the pad electrodes PDE disposed in the pad area PA may transmit the first power voltage VDDN to the first to third light-emitting-element layers LDL1, LDL2, and LDL3 and the first to third conductive layers CDL1, CDL2, and CDL3.

The first bonding pattern BDP1 included in the display element layer DPL and the first reflective pattern RFP1 on the first bonding pattern BDP1 may be integrally formed in the pad area PA. Here, the first bonding pattern BDP1 disposed in the pad area PA may be spaced apart from and not be connected to the first bonding pattern BDP1 disposed in the non-display area NDA.

The pad electrodes PDE that are disposed in the pad area PA and configured to supply the first power voltage VDDN may be connected to the third conductive layer CDL3, the third conductive patterns CDP3, and the third light emitting element LD3 so that the first power voltage VDDN can be transmitted to the third conductive layer CDL3, the third conductive patterns CDP3, and the third light emitting element LD3 through the pad electrodes PDE.

Accordingly, a same voltage may be transmitted to the N-type semiconductor layer and the P-type semiconductor layer of each of the 1-1-th light emitting element LD1-1, the 1-2-th light emitting element LD1-2, the second light emitting element LD2, and the third light emitting element LD3, such that the 1-1-th light emitting element LD1-1, the 1-2-th light emitting element LD1-2, the second light emitting element LD2, and the third light emitting element LD3 that are disposed in the pad area PA may not emit light.

In an embodiment, the pad electrodes PDE that are disposed in the pad area PA and configured to supply the first power voltage VDDN may transmit the first power voltage VDDN to the third conductive layer CDL3, the third conductive patterns CDP3, and the third light emitting element LD3.

In an embodiment, the first power voltage VDDN may be transmitted from the third conductive layer CDL3 to the N-type semiconductor layer of the third light emitting element LD3. In addition, since the third conductive layer CDL3 and the second conductive layer CDL2 are connected to each other by the third conductive patterns CDP3, the first power voltage VDDN may be transmitted from the second conductive layer CDL2 to the N-type semiconductor layer of the second light emitting element LD2. In such an embodiment, since the second conductive layer CDL2 and the first conductive layer CDL1 are connected to each other through the second conductive patterns CDP2, the first power voltage VDDN may be transmitted from the first conductive layer CDL1 to the N-type semiconductor layer of each of the 1-1-th light emitting element LD1-1 and the 1-2-th light emitting element LD1-2.

In such an embodiment, since the first conductive layer CDL1 is connected to the first bonding pattern BDP1 and the first reflective pattern RFP1 by the first conductive patterns CDP1, the first power voltage VDDN may be transmitted to the 1-1-th light emitting element LD1-1, the 1-2-th light emitting element LD1-2, the first connection pattern CNP1, and the second connection pattern CNP2 that are connected to the first bonding pattern BDP1 and the first reflective pattern RFP1. In other words, the first power voltage VDDN may be transmitted to the P-type semiconductor layer of each of the 1-1-th light emitting element LD1-1, the 1-2-th light emitting element LD1-2, the second light emitting element LD2, and the third light emitting element LD3. Therefore, a same voltage may be transmitted to the N-type semiconductor layer and the P-type semiconductor layer of each of the 1-1-th light emitting element LD1-1, the 1-2-th light emitting element LD1-2, the second light emitting element LD2, and the third light emitting element LD3, so that the 1-1-th light emitting element LD1-1, the 1-2-th light emitting element LD1-2, the second light emitting element LD2, and the third light emitting element LD3 may not emit light.

In an embodiment, the first bonding pattern BDP1 and the first reflective pattern RFP1 may transmit the first power voltage VDDN to the pixel circuit layer PCL. The pixel circuit layer PCL in the pad area PA may be connected to the pixel circuit layer PCL in the display area DA, and may transmit the first power voltage VDDN to the P-type semiconductor layer of each of the 1-1-th light emitting element LD1-1, the 1-2-th light emitting element LD1-2, the second light emitting element LD2, and the third light emitting element LD3 through the pixel circuit layer PCL in the display area DA. Therefore, the 1-1-th light emitting element LD1-1, the 1-2-th light emitting element LD1-2, the second light emitting element LD2, and the third light emitting element LD3 in the display area DA may each receive the first power voltage VDDN by the P-type semiconductor layer thereof and receive the second power voltage VSSN by the N-type semiconductor layer thereof, thereby generating light using a voltage difference.

Accordingly, to ensure uniform quality in the fabrication process, a structure may be configured in a way such that light emitting elements LD are arranged in the pad area PA, while light is not emitted from the pad area PA.

In an embodiment, the display panel DP may include the first to third light-emitting-element layers LDL1, LDL2, and LDL3 that respectively include the light emitting elements LD configured to generate different colors of light, and the light emitting elements LD may be disposed to be spaced apart from each other in a plan view. Accordingly, the reliability of each of the light emitting elements LD can be enhanced, and the aperture ratio for each sub-pixel area may be maximized.

In such an embodiment, since each of the first to third light-emitting-element layers LDL1, LDL2, and LDL3 further includes conductive patterns CDP in a mesh structure that are arranged in the entire area of the display panel DP and are connected to each other, a voltage drop (IR Drop) phenomenon in which the voltage drops due to resistance as approaching a central portion of the display area DA may be reduced. As a result, the contact resistance may also be minimized.

In such an embodiment, since each of the conductive patterns CDP includes the reflective electrode RFE on a side surface thereof, light generated from the light emitting elements LD may be reflected by the reflective electrode RFE to be emitted through the display surface of the display panel DP. Hence, the light output efficiency of the display device may be enhanced.

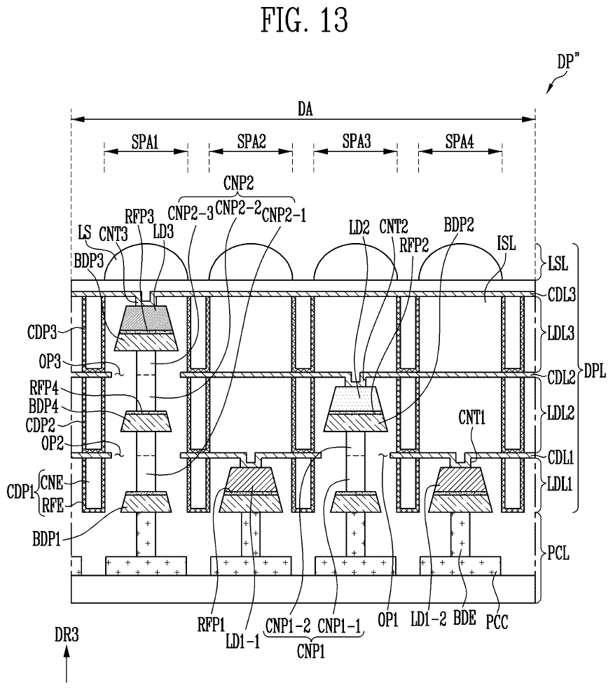

FIG. 13 is a sectional view illustrating another embodiment of FIG. 7.

A display panel DP″ in accordance with the embodiment shown in FIG. 13 is substantially the same as the display panel DP described above with reference to FIG. 7 except that the first to third bridge patterns BRP1, BRP2, and BRP3 of FIG. 7 are omitted or replaced with a fourth bonding pattern BDP4 and a fourth reflective pattern RFP4. Accordingly, any repetitive detailed description of the same or like elements as those described above will be omitted or simplified.

Referring to FIG. 13, in the display area DA, the second light-emitting-element layer LDL2 may further include the fourth bonding pattern BDP4, and the fourth reflective pattern RFP4 disposed on the fourth bonding pattern BDP4. The fourth bonding pattern BDP4 and the fourth reflective pattern RFP4 may overlap the first sub-pixel area SPA1, and may overlap the second bonding pattern BDP2 and the second reflective pattern RFP2 in the horizontal direction perpendicular to the third direction DR3.

In an embodiment, the first conductive layer CDL1 may not include the first and second bridge patterns BRP1 and BRP2 of FIG. 7, and may define a first opening OP1 overlapping the third sub-pixel area SPA3 and a second opening OP2 overlapping the first sub-pixel area SPA1. In such an embodiment, the second conductive layer CDL2 may not include the third bridge pattern BRP3 of FIG. 7, and may define a third opening OP3 overlapping the first sub-pixel area SPA1. Accordingly, each of the first to third openings OP1, OP2, and OP3 may have a circular or rectangular shape rather than having an annular shape in a plan view.

The 1-1-th connection pattern CNP1-1 and the 1-2-th connection pattern CNP1-2 may contact each other through the first opening OP1, and may be directly connected to each other.

The 2-1-th connection pattern CNP2-1 and the 2-2-th connection pattern CNP2-2 may be brought into contact with and directly connected to each other through the second opening OP2. The 2-2-th connection pattern CNP2-2 and the 2-3-th connection pattern CNP2-3 may be brought into contact with and directly connected to each other through the third opening OP3. Furthermore, the 2-2-th connection pattern CNP2-2 may be divided into two parts, which are connected to each other by the fourth bonding pattern BDP4 and the fourth reflective pattern RFP4.

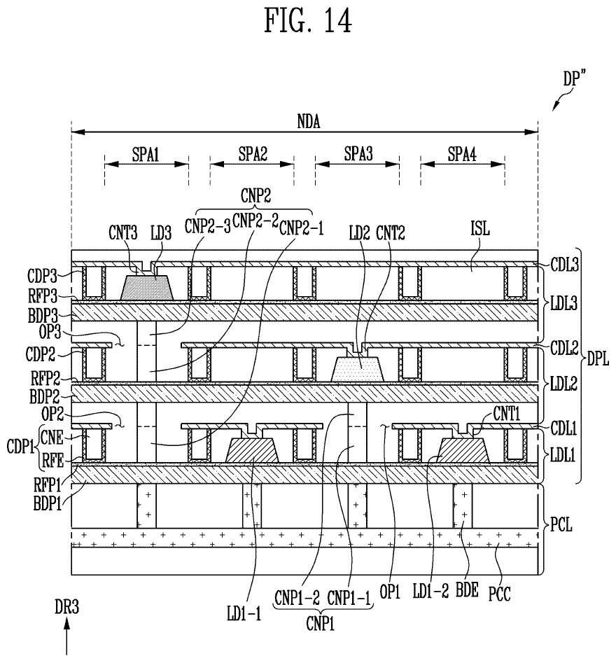

FIG. 14 is a sectional view illustrating another embodiment of FIG. 10.

A display panel DP″ in accordance with the embodiment shown in FIG. 14 is substantially the same as the display panel DP described above with reference to FIG. 10 except that the first to third bridge patterns BRP1, BRP2, and BRP3 of FIG. 10 are omitted, and the first to third bonding patterns BDP1, BDP2, and BDP3 and the first to third reflective patterns RFP1, RFP2, and RFP3 each integrally extend in the non-display area NDA. Accordingly, any repetitive detailed description of the same or like elements as those described above will be omitted or simplified.

Referring further to FIG. 14, in the non-display area NDA, the first bonding pattern BDP1 and the first reflective pattern RFP1 of the first light-emitting-element layer LDL1 may integrally extend as a whole, the second bonding pattern BDP2 and the second reflective pattern RFP2 of the second light-emitting-element layer LDL2 may integrally extend as a whole, and the third bonding pattern BDP3 and the third reflective pattern RFP3 of the third light-emitting-element layer LDL3 may integrally extend as a whole. In other words, since the first to third bonding patterns BDP1, BDP2, and BDP3 and the first to third reflective patterns RFP1, RFP2, and RFP3 each integrally extend as a whole in the non-display area NDA, signals supplied from the pixel circuit layer PCL (e.g., the second power voltage VSSN) may be transmitted to the first to third light-emitting-element layers LDL1, LDL2, and LDL3 through the first to third bonding patterns BDP1, BDP2, and BDP3 and the first to third reflective patterns RFP1, RFP2, and RFP3.

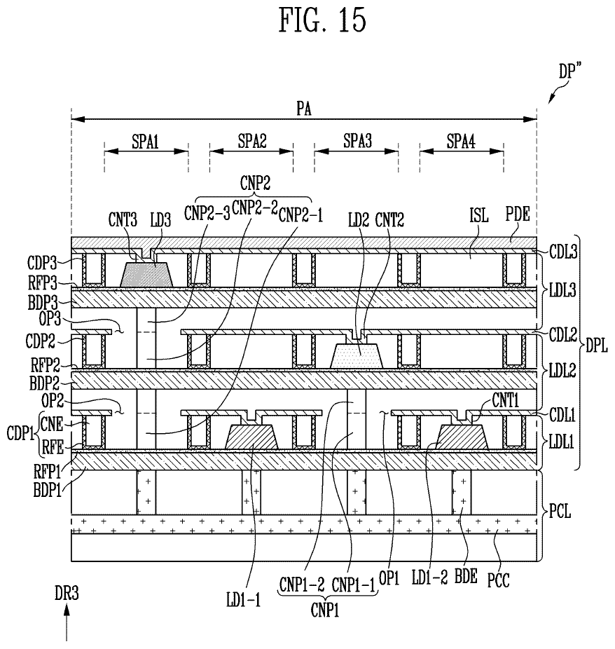

FIG. 15 is a sectional view illustrating another embodiment of FIG. 12.

A display panel DP″ in accordance with the embodiment shown in FIG. 15 is substantially the same as the display panel DP described above with reference to FIG. 12 except that the first to third bridge patterns BRP1, BRP2, and BRP3 of FIG. 12 are omitted, and the first to third bonding patterns BDP1, BDP2, and BDP3 and the first to third reflective patterns RFP1, RFP2, and RFP3 each integrally extend in the pad area PA. Accordingly, any repetitive detailed description of the same or like elements as those described above will be omitted or simplified.

Referring further to FIG. 15, in the pad area PA, the first bonding pattern BDP1 and the first reflective pattern RFP1 of the first light-emitting-element layer LDL1 may integrally extend as a whole, the second bonding pattern BDP2 and the second reflective pattern RFP2 of the second light-emitting-element layer LDL2 may integrally extend as a whole, and the third bonding pattern BDP3 and the third reflective pattern RFP3 of the third light-emitting-element layer LDL3 may integrally extend as a whole. In other words, since the first to third bonding patterns BDP1, BDP2, and BDP3 and the first to third reflective patterns RFP1, RFP2, and RFP3 each integrally extend as a whole in the pad area PA, signals supplied from the pad electrodes PDE (e.g., the second power voltage VSSN) may be transmitted to the first to third light-emitting-element layers LDL1, LDL2, and LDL3 through the first to third bonding patterns BDP1, BDP2, and BDP3 and the first to third reflective patterns RFP1, RFP2, and RFP3.

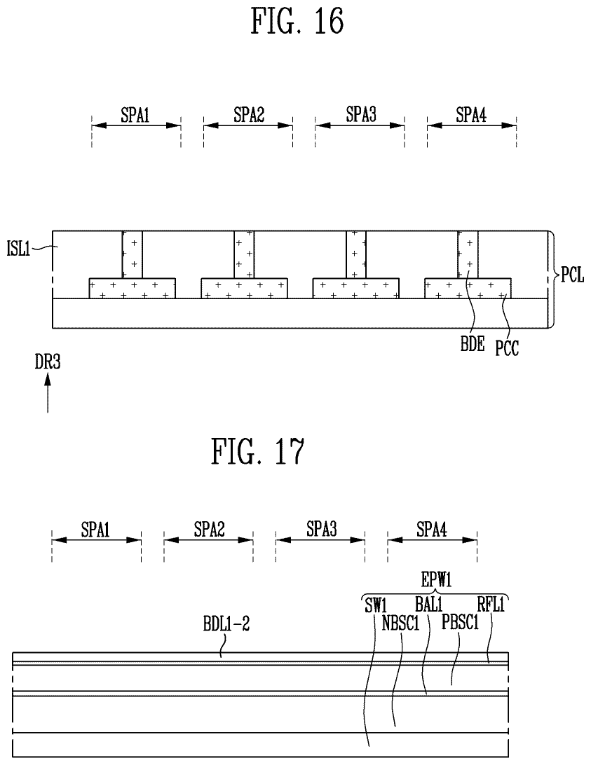

FIGS. 16 to 46 are diagrams illustrating a method of fabricating the display device DD (or the display panel DP) in accordance with an embodiment of the disclosure.

FIGS. 16 to 46 illustrate an embodiment of a method of fabricating the display panel DP shown in FIGS. 1 to 8. Particularly, FIGS. 16 to 46 illustrate the method of fabricating the display panel DP disposed in the display area DA. Accordingly, any repetitive detailed description of the same or like elements as those described above will be omitted or simplified.

Referring to FIG. 16, in an embodiment of a method of fabricating the display panel DP, the pixel circuit layer PCL including the pixel circuits PCC and the bonding electrodes BDE may be formed. The bonding electrodes BDE may respectively overlap (or be formed in) the first to fourth sub-pixel areas SPA1, SPA2, SPA3, and SPA4, and may be respectively disposed on and connected to the pixel circuits PCC. Furthermore, a first insulating layer ISL1 may be formed around the pixel circuits PCC and the bonding electrodes BDE. The first insulating layer ISL1 may include or be formed of oxide.

Referring to FIGS. 17 to 28, the first light-emitting-element layer LDL1 may be formed on the pixel circuit layer PCL.

Referring to FIG. 17, in an embodiment, a first epitaxial wafer substrate EPW1 may be formed or prepared. The first epitaxial wafer substrate EPW1 may include a first silicon wafer SW1, a first N-type base semiconductor layer NBSC1 on the first silicon wafer SW1, a first base active layer BAL1 on the first N-type base semiconductor layer NBSC1, a first P-type base semiconductor layer PBSC1 on the first base active layer BAL1 and a first reflective layer RFL1 on the first P-type base semiconductor layer PBSC1, and a 1-2-th bonding layer BDL1-2 may be further formed on the first epitaxial wafer substrate EPW1, i.e., on the first reflective layer RFL1.

The first silicon wafer SW1 may be a base plate for growing a target material. In an embodiment, for example, the first silicon wafer SW1 may be a wafer for epitaxial growth of the target material. Although the first silicon wafer SW1 may be a silicon substrate in an embodiment, the material for forming the first silicon wafer SW1 is not limited thereto.

The first N-type base semiconductor layer NBSC1 may be epitaxially grown on the first silicon wafer SW1. The first N-type base semiconductor layer NBSC1 may include or be formed of at least one selected from materials constituting the first semiconductor layer 21 described above with reference to FIG. 8. In an embodiment, for example, the first N-type base semiconductor layer NBSC1 may include a gallium nitride (GaN) semiconductor material doped with a first conductive dopant (or an n-type dopant).

The first base active layer BAL1 may be epitaxially grown on the first N-type base semiconductor layer NBSC1. The first base active layer BAL1 may be formed using one of the structures corresponding to the active layer 22 described above with reference to FIG. 8 The first P-type base semiconductor layer PBSC1 may be epitaxially grown on the first base active layer BAL1. The first P-type base semiconductor layer PBSC1 may include or be formed of at least one selected from materials constituting the second semiconductor layer 23 described with reference to FIG. 8. In an embodiment, for example, the first P-type base semiconductor layer PBSC1 may include a gallium nitride (GaN) semiconductor material doped with a second conductive dopant (or a P-type dopant).

The first reflective layer RFL1 may be formed on the first P-type base semiconductor layer PBSC1. The first reflectively layer RFL1 may include or be formed of aluminum.

The 1-2-th bonding layer BDL1-2 may be formed on the first reflective layer RFL1. The 1-2-th bonding layer BDL1-2 may include or be formed of titanium.

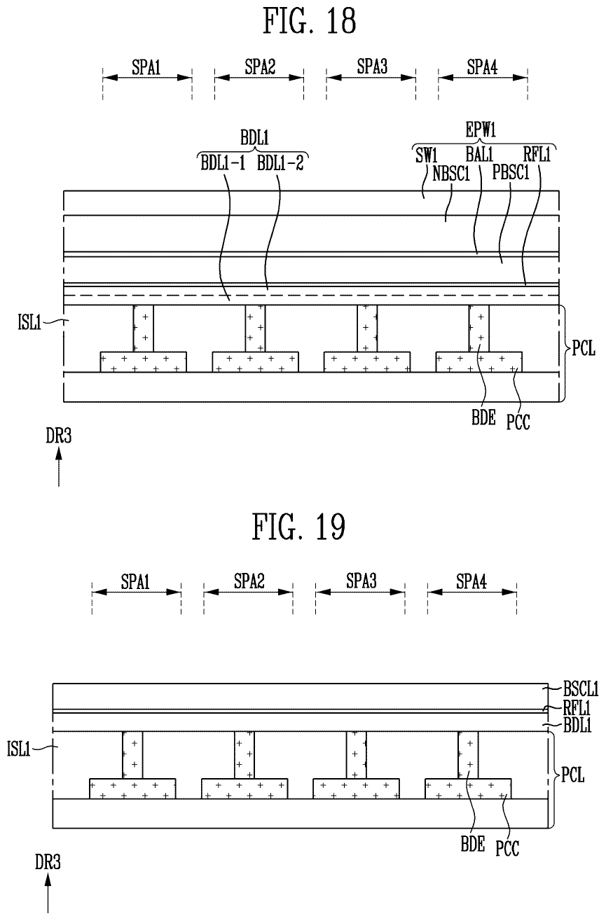

Referring to FIG. 18, a 1-1-th bonding layer BDL1-1 may be formed on the pixel circuit layer PCL. The 1-1-th bonding layer BDL1-1 may include or be formed of titanium.

Thereafter, the pixel circuit layer PCL and the first epitaxial wafer substrate EPW1 may be coupled to each other in a way such that the 1-1-th bonding layer BDL1-1 and the 1-2-th bonding layer BDL1-2 face each other. Accordingly, the 1-1-th bonding layer BDL1-1 and the 1-2-th bonding layer BDL1-2 may be coupled to each other, thereby forming a double-layered first bonding layer BDL1.

The first epitaxial wafer substrate EPW1 may have a structure in which the 1-2-th bonding layer BDL1-2, the first reflective layer RFL1, the first P-type base semiconductor layer PBSC1, the first base active layer BAL1, the first N-type base semiconductor layer NBSC1, and the first silicon wafer SW1 are stacked in the third direction DR3, and may be coupled to the pixel circuit layer PCL.

Referring to FIG. 19, a first base semiconductor layer BSCL1 may be formed by removing portions of (or by patterning) the first silicon wafer SW1 and the first N-type base semiconductor layer NBSC1 from the first epitaxial wafer substrate EPW1. The first base semiconductor layer BSCL1 may include the first P-type base semiconductor layer PBSC1, the first base active layer BAL1, and the first N-type base semiconductor layer NBSC1.

In an embodiment where the display panel is a high-resolution display panel, the first base semiconductor layer BSCL1 may have a thickness of approximately 1 micrometer or less.

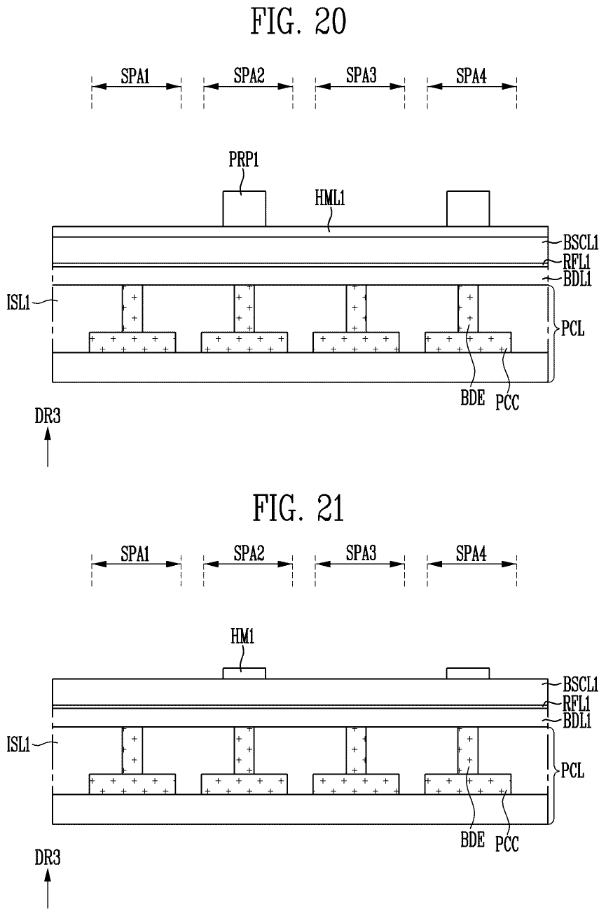

Referring to FIGS. 20 to 22, the first base semiconductor layer BSCL1 may be patterned to form the first light emitting element LD1.

Referring to FIG. 20, a first hard mask layer HML1 may be formed on the first base semiconductor layer BSCL1. The first hard mask layer HML1 may include or be formed of a same material as the first insulating layer ISL1. In an embodiment, the first hard mask layer HML1 may include or be formed of oxide.

First photoresist patterns PRP1 may be formed on the first hard mask layer HML1. The first photoresist patterns PRP1 may be respectively formed in the second sub-pixel area SPA2 and the fourth sub-pixel area SPA4.

Referring to FIG. 21, the first hard mask layer HML1 may be patterned using the first photoresist patterns PRP1. Therefore, first hard mask patterns HM1 may be formed to respectively overlap the second sub-pixel area SPA2 and the fourth sub-pixel area SPA4.

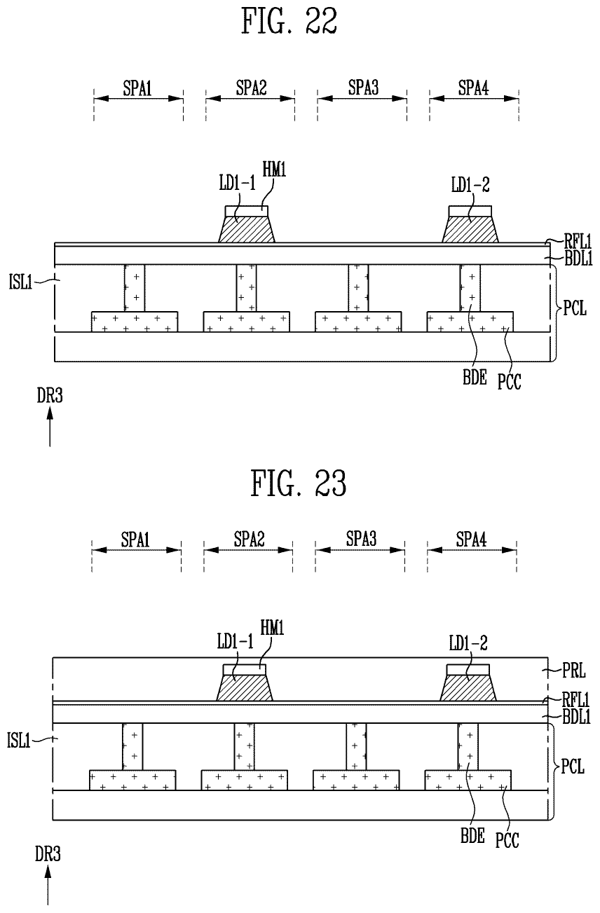

Referring to FIG. 22, the first base semiconductor layer BSCL1 may be patterned using the first hard mask patterns HM1. As a result, the 1-1-th light emitting element LD1-1 and the 1-2-th light emitting element LD1-2, respectively overlapping the second sub-pixel area SPA2 and the fourth sub-pixel area SPA4, may be formed.

Referring to FIG. 23, the photoresist layer PRL may be formed on the first reflective layer RFL1 to cover the first hard mask patterns HM1, the 1-1-th light emitting element LD1-1, and the 1-2-th light emitting element LD1-2.

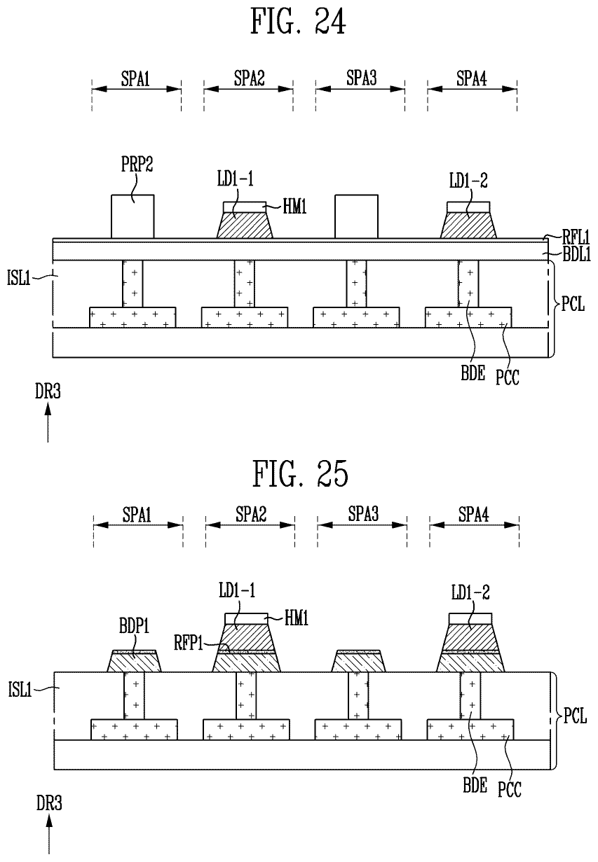

Referring to FIG. 24, the photoresist layer PRL may be exposed and developed to form second photoresist patterns PRP2 that respectively overlap the first sub-pixel area SPA1 and the third sub-pixel area SPA3 where the 1-1-th light emitting element LD1-1 and the 1-2-th light emitting element LD1-2 are not formed.

Referring to FIG. 25, the first reflective layer RFL1 and the first bonding layer BDL1 may be patterned using the second photoresist patterns PRP2, the 1-1-th light emitting element LD1-1, and the 1-2-th light emitting element LD1-2. As a result, the first bonding patterns BDP1 may be formed to respectively overlap the first to fourth pixel areas SPA1, SPA2, SPA3, and SPA4 and to be spaced apart from each other, and the first reflective patterns RFP1 may be formed to be respectively disposed on the first bonding patterns BDP1. Accordingly, in the second and fourth sub-pixel areas SPA2 and SPA4, the 1-1-th light emitting element LD1-1 and the 1-2-th light emitting element LD1-2 may be respectively disposed on the first bonding patterns BDP1 and the first reflective patterns RFP1.

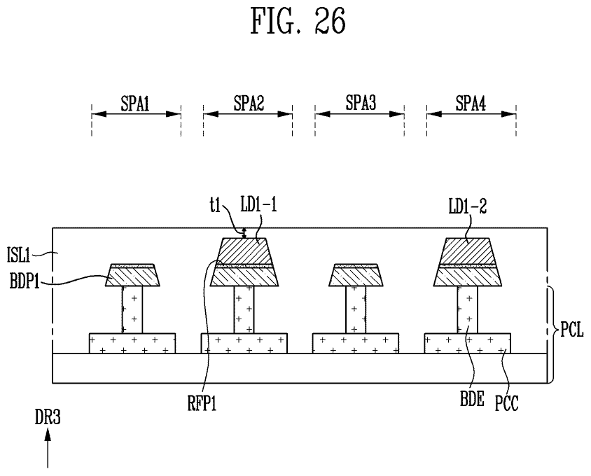

Referring to FIG. 26, the first insulating layer ISL1 may be thereafter formed to cover the first bonding patterns BDP1, the first reflective patterns RFP1, the 1-1-th light emitting element LD1-1, and the 1-2-th light emitting element LD1-2. Since the first hard mask patterns HM1 is formed using a same material as the first insulating layer ISL1, the first hard mask patterns HM1 may be included in the first insulating layer ISL1 without being removed.

An upper surface of the first insulating layer ISL1 may be planarized in a way such that a distance t1 between an upper surface of each of the 1-1-th light emitting element LD1-1 and the 1-2-th light emitting element LD1-2 and the upper surface of the first insulating layer ISL1 becomes approximately 300 nm.

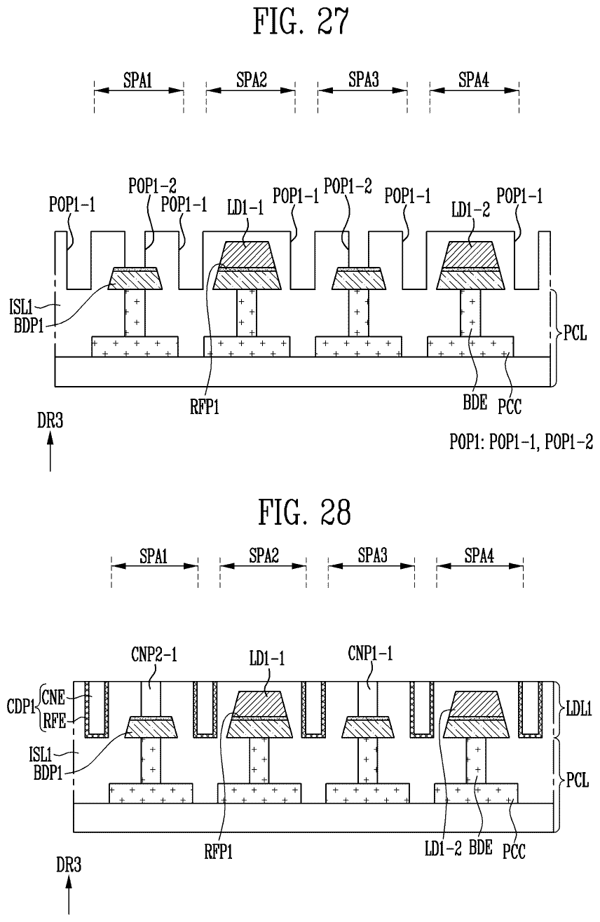

Referring to FIG. 27, first pattern openings POP1 may be formed in the first insulating layer ISL1 disposed on the pixel circuit layer PCL. The first pattern openings POP1 may have the form of grooves on the first insulating layer ISL1 formed on the pixel circuit layer PCL. The first pattern openings POP1 may include first first pattern openings (hereinafter, will be referred to as “1-1-th pattern openings”) POP1-1 formed between the first to fourth sub-pixel areas SPA1, SPA2, SPA3, and SPA4, and first second pattern openings (hereinafter, will be referred to as “1-2-th pattern openings POP1-2”) formed in the first and second sub-pixel areas SPA1 and SPA3. Therefore, the 1-1-th pattern openings POP1-1 may be spaced apart from the first bonding patterns BDP1, the first reflective patterns RFP1, the 1-1-th light emitting element LD1-1, and the 1-2-th light emitting element LD1-2. The 1-2-th pattern openings POP1-2 may respectively expose the first reflective patterns RFP1.

The 1-1-th pattern openings POP1-1 and the 1-2-th pattern openings POP1-2 may be formed through separate processes. However, the disclosure is not limited to the foregoing example, and the 1-1-th pattern openings POP1-1 and the 1-2-th pattern openings POP1-2 may be simultaneously formed in another embodiment.

Referring to FIG. 28, the reflective electrode RFE may be formed in each of the 1-1-th pattern openings POP1-1. The reflective electrode RFE may be deposited with a constant thickness in each of the 1-1-th pattern openings POP1-1. The reflective electrode RFE may include or be formed of at least one selected from aluminum and silver. Furthermore, the connection electrode CNE may be formed in each of the 1-1-th pattern openings POP1-1. The connection electrode CNE may be formed by filling an internal space of the reflective electrode RFE therewith. The connection electrode CNE may include or be formed of at least one selected from copper and tungsten. The reflective electrode RFE and the connection electrode CNE may be formed in each of the 1-1-th pattern openings POP1-1, and the upper surface may be planarized through a chemical mechanical polishing (CMP) process. As a result, the first conductive patterns CDP1 may be respectively formed in the 1-1-th pattern openings POP1-1.

In such an embodiment, the connection patterns CNP1-1 and CNP2-1 may be respectively formed in the 1-2-th pattern openings POP1-2. The 1-1-th connection pattern CNP1-1 may be formed in the 1-2-th pattern opening POP1-2 that overlaps the third sub-pixel area SPA3. The 2-1-th connection pattern CNP2-1 may be formed in the 1-2-th pattern opening POP1-2 that overlaps the first sub-pixel area SPA1. The 1-1-th connection pattern CNP1-1 and the 2-1-th connection pattern CNP2-1 may include or be formed of a same material as the connection electrode CNE.

The first conductive patterns CDP1 may be formed through a process separate from the 1-1-th connection pattern CNP1-1 and the 2-1-th connection pattern CNP2-1. However, the disclosure is not limited to the aforementioned example. The first conductive patterns CDP1 may be formed simultaneously with the 1-1-th connection pattern CNP1-1 and the 2-1-th connection pattern CNP2-1. In an embodiment where the first conductive patterns CDP1 is formed simultaneously with the 1-1-th connection pattern CNP1-1 and the 2-1-th connection pattern CNP2-1, the first conductive patterns CDP1 may have a same structure as the 1-1-th connection pattern CNP1-1 and the 2-1-th connection pattern CNP2-1. In other words, a reflective electrode may further be formed on a side surface and a lower surface of each of the 1-1-th connection pattern CNP1-1 and the 2-1-th connection pattern CNP2-1.

The first light-emitting-element layer LDL1 including the first bonding patterns BDP1, the first reflective patterns RFP1, at least one first light emitting element LD1, the first conductive patterns CDP1, the 1-1-th connection pattern CNP1-1, and the 1-2-th connection pattern CNP2-2 may be formed through the above-described processes.

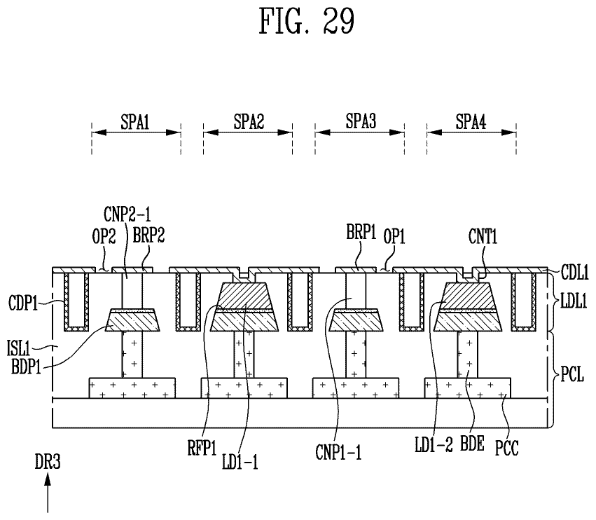

Referring to FIG. 29, the first contact holes CNT1 may be respectively formed in the first insulating layer ISL1 over the 1-1-th light emitting element LD1-1 and the 1-2-th light emitting element LD1-2 in a way such that the 1-1-th light emitting element LD1-1 and the 1-2-th light emitting element LD1-2 are exposed through the first contact holes CNT1.

The first conductive layer CDL1 may be formed on the first light emitting element layer LDL1. The first conductive layer CDL1 may contact the 1-1-th light emitting element LD1-1 and the 1-2-th light emitting element LD1-2 through the respective first contact holes CNT1. Furthermore, the first conductive layer CDL1 may also contact the first conductive patterns CDP1, and may cover the upper surface of each of the first conductive patterns CDP1. The first conductive layer CDL1 may include or be formed of indium tin oxide.

The first opening OP1 overlapping the third sub-pixel area SPA3 and the second opening OP2 overlapping the first sub-pixel area SPA1 may be formed in the first conductive layer CDL1. In an embodiment, since the first opening OP1 has an annular shape in a plan view, the first bridge pattern BRP1 may be formed in a central portion of the first opening OP1 to be spaced apart from other portions of the first conductive layer CDL1. The first bridge pattern BRP1 may cover the exposed upper surface of the 1-1-th connection pattern CNP1-1. In such an embodiment, since the second opening OP2 has an annular shape in a plan view, the second bridge pattern BRP2 may be formed in a central portion of the second opening OP2 to be spaced apart from other portions of the first conductive layer CDL1. The second bridge pattern BRP2 may cover the exposed upper surface of the 2-1-th connection pattern CNP2-1.

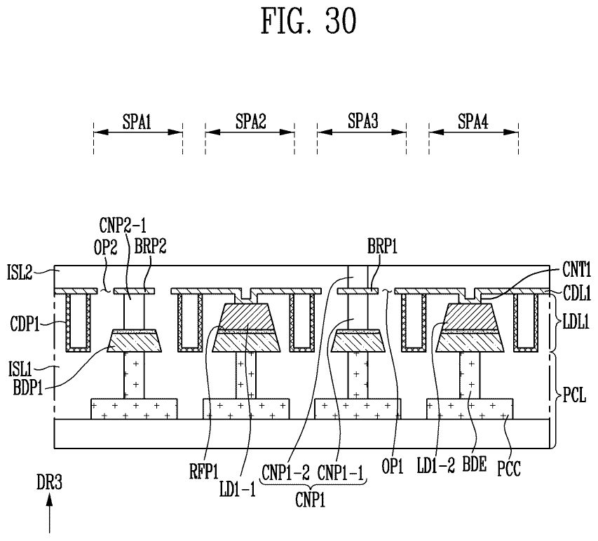

Referring to FIG. 30, a second insulating layer ISL2 may be formed on the first conductive layer CDL1. A contact hole, which overlaps the third sub-pixel area SPA3 and exposes at least a portion of the first bridge pattern BRP1, may be formed in the second insulating layer ISL2. The 1-2-th connection pattern CNP1-2 may be formed in the contact hole. Therefore, the 1-2-th connection pattern CNP1-2 may be formed on and connected to the first bridge pattern BRP1.

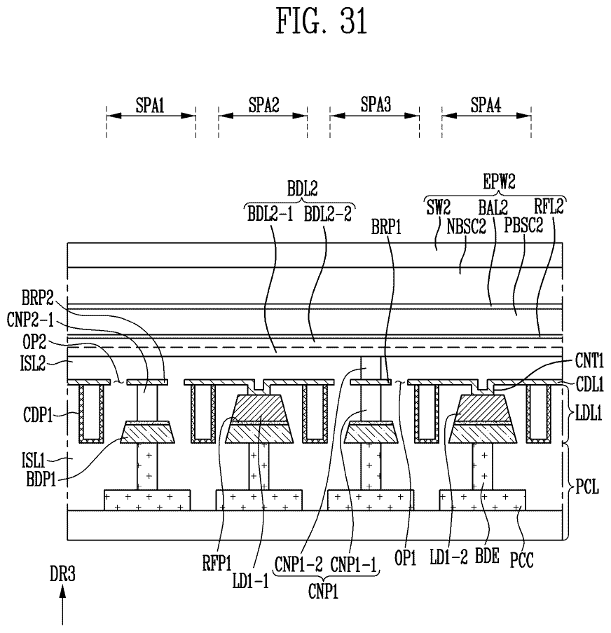

Referring to FIG. 31, a second first bonding layer (hereinafter will be referred to as “2-1-th bonding layer”) BDL2-1 may be formed on the second insulating layer ISL2. The 2-1-th bonding layer BDL2-1 may include or be formed of titanium. Furthermore, a second epitaxial wafer substrate EPW2 including a second silicon wafer SW2, a second N-type base semiconductor layer NBSC2, a second base active layer BAL2, a second P-type base semiconductor layer PBSC2, a second reflective layer RFL2, and a 2-2-th bonding layer BDL2-2 may be formed or prepared.

Thereafter, the first light-emitting-element layer LDL1 and the second epitaxial wafer substrate EPW2 may be coupled to each other in a way such that the 2-1-th bonding layer BDL2-1 and the 2-2-th bonding layer BDL2-2 face each other. Accordingly, the 2-1-th bonding layer BDL2-1 and the 2-2-th bonding layer BDL2-2 may be coupled to each other, thereby forming a double-layered second bonding layer BDL2.

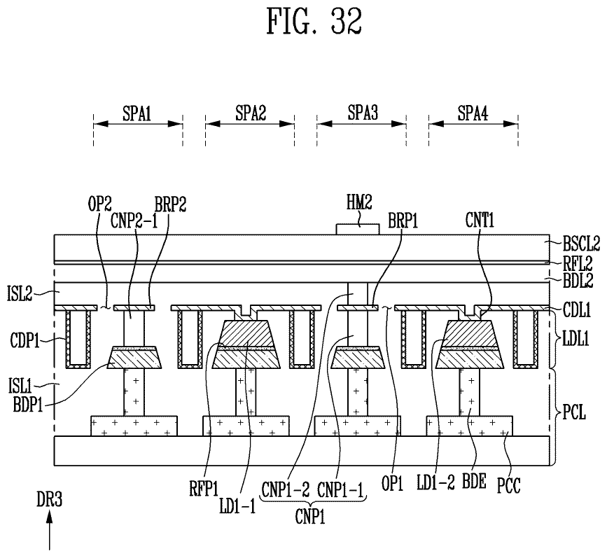

Referring to FIG. 32, a second base semiconductor layer BSCL2 may be formed by removing portions of the second silicon wafer SW2 and the second N-type base semiconductor layer NBSC2 from the second epitaxial wafer substrate EPW2. The second base semiconductor layer BSCL2 may include the second P-type base semiconductor layer PBSC2, the second base active layer BAL2, and the second N-type base semiconductor layer NBSC2.

A second hard mask pattern HM2 may be formed on the second base semiconductor layer BSCL2. The second hard mask pattern HM2 may be formed of a same material as the second insulating layer ISL2. In an embodiment, the second hard mask pattern HM2 may include or be formed of oxide.

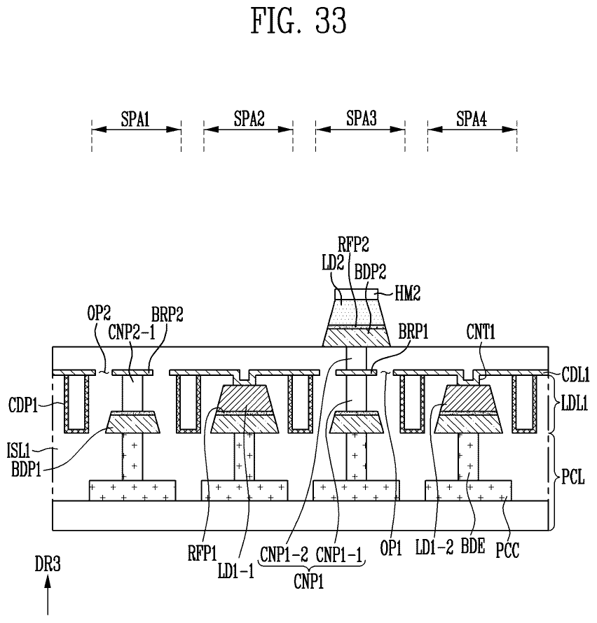

Referring to FIG. 33, the second base semiconductor layer BSCL2, the second reflective layer RFL2, and the second bonding layer BDL2 may be patterned using the second hard mask pattern HM2. Therefore, the second light emitting element LD2, the second reflective pattern RFP2, and the second bonding pattern BDP2, which overlap the third sub-pixel area SPA3, may be formed.

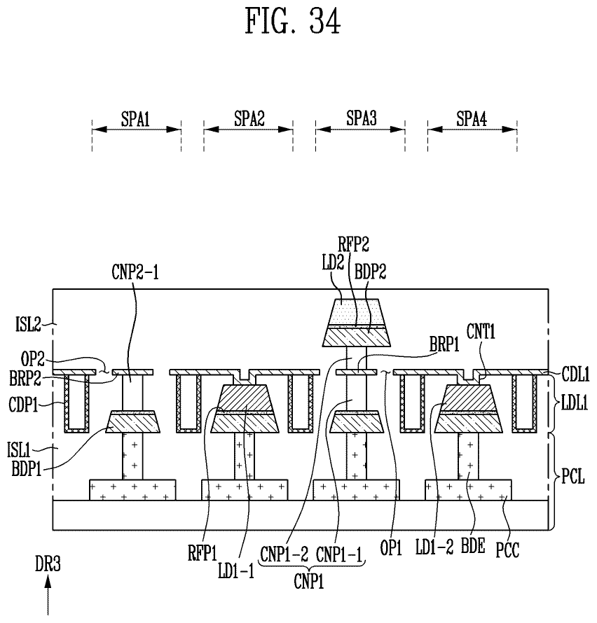

Referring to FIG. 34, the second insulating layer ISL2 may be further formed to cover the second bonding pattern BDP2, the second reflective pattern RFP2, and the second light emitting element LD2. Since the second hard mask pattern HM2 is formed using a same material as the second insulating layer ISL2, the second hard mask pattern HM2 may be included in the second insulating layer ISL2 without being removed.

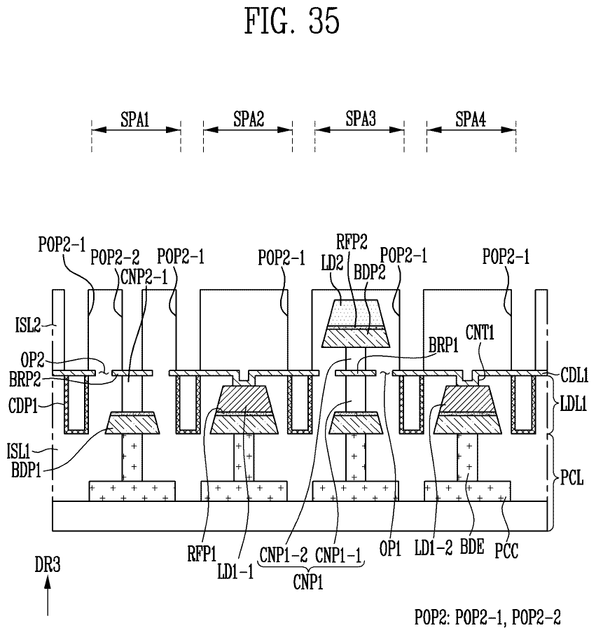

Referring to FIG. 35, second pattern openings POP2 may be formed in the second insulating layer ISL2 disposed on the first conductive layer CDL1. The second pattern openings POP2 may include second first pattern openings (hereinafter, will be referred to as “2-1-th pattern openings”) POP2-1 formed between the first to fourth sub-pixel areas SPA1, SPA2, SPA3, and SPA4, and a second second pattern opening (hereinafter, will be referred to as “2-2-th pattern opening”) POP2-2 formed in the first sub-pixel area SPA1. Accordingly, the 2-1-th pattern openings POP2-1 may be spaced apart from the second bonding pattern BDP2, the second reflective pattern RFP2, and the second light emitting element LD2. The 2-2-th pattern opening POP2-2 may expose the second bridge pattern BRP2.

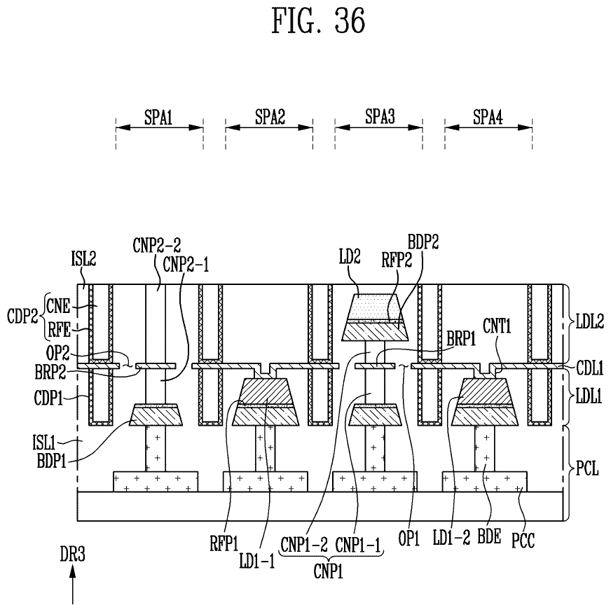

Referring to FIG. 36, the reflective electrode RFE may be formed in each of the 2-1-th pattern openings POP2-1. Furthermore, the connection electrode CNE may be formed in each of the 2-1-th pattern openings POP2-1 by filling an internal space of the reflective electrode RFE therewith. The reflective electrode RFE and the connection electrode CNE may be formed in each of the 2-1-th pattern openings POP2-1, and the upper surface may be planarized through a CMP process. As a result, the second conductive patterns CDP2 may be respectively formed in the 2-1-th pattern openings POP2-1.

In an embodiment, the 2-2-th connection pattern CNP2-2 may be formed in the 2-2-th pattern opening POP2-2. The 2-2-th connection pattern CNP2-2 may include or be formed of a same material as the connection electrode CNE.

The second light-emitting-element layer LDL2 including the second bonding pattern BDP2, the second reflective pattern RFP2, the second light emitting element LD2, the second conductive patterns CDP2, and the 2-2-th connection pattern CNP2-2 may be formed through the above-described processes.

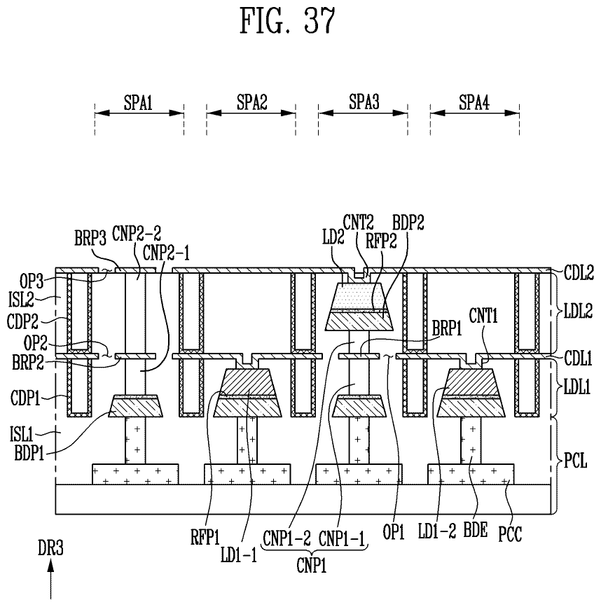

Referring to FIG. 37, the second contact hole CNT2, exposing the second light emitting element LD2, may be formed in the second insulating layer ISL2 on the second light emitting element LD2.

The second conductive layer CDL2 may be formed on the second light emitting element layer LDL2. The second conductive layer CDL2 may contact the second light emitting element LD2 through the second contact hole CNT2. Furthermore, the second conductive layer CDL2 may also contact the second conductive patterns CDP2, and may cover the upper surface of each of the second conductive patterns CDP2.

In an embodiment, the third opening OP3 overlapping the first sub-pixel area SPA1 may be formed in the second conductive layer CDL2. Since the third opening OP3 has an annular shape in a plan view, the third bridge pattern BRP3 may be formed in a central portion of the third opening OP3 to be spaced apart from other portions of the third conductive layer CDL3. The third bridge pattern BRP3 may cover the exposed upper surface of the 2-2-th connection pattern CNP2-2.

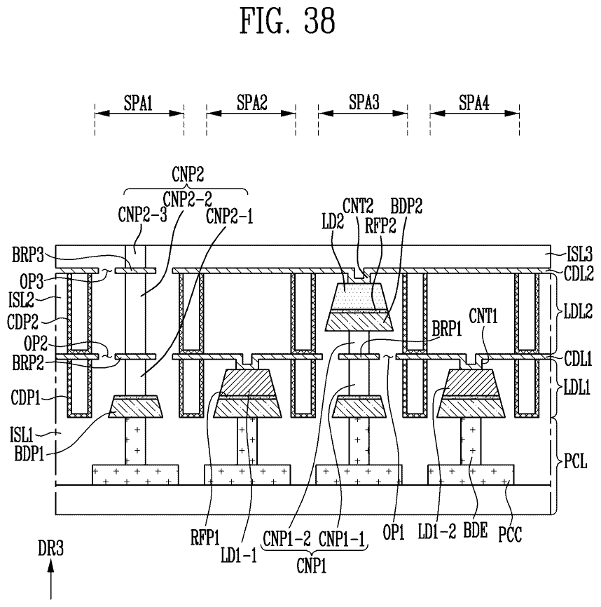

Referring to FIG. 38, a third insulating layer ISL3 may be formed on the second conductive layer CDL2. A contact hole, which overlaps the first sub-pixel area SPA1 and exposes at least a portion of the third bridge pattern BRP3, may be formed in the third insulating layer ISL3. The 2-3-th connection pattern CNP2-3 may be formed in the contact hole. Therefore, the 2-3-th connection pattern CNP2-3 may be formed on and connected to the third bridge pattern BRP3.

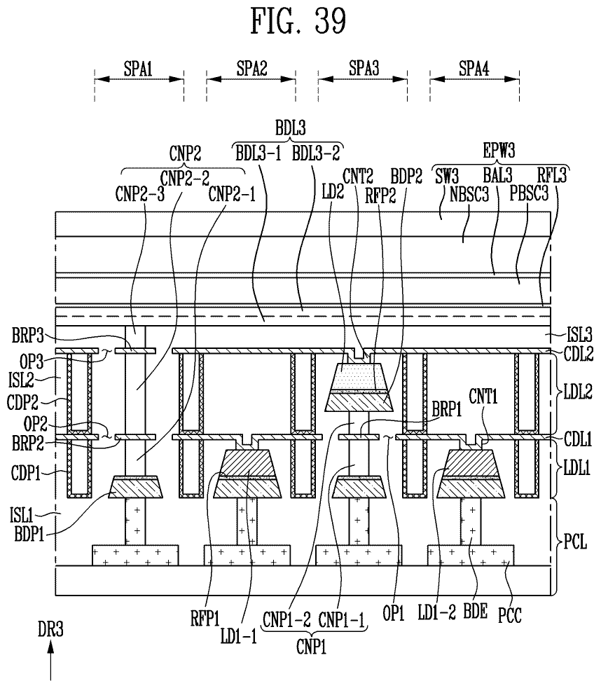

Referring to FIG. 39, the 3-1-th bonding layer BDL3-1 may be formed on the third insulating layer ISL3. Furthermore, there may be formed a third epitaxial wafer substrate EPW3 including a third silicon wafer SW3, a third N-type base semiconductor layer NBSC3, a third base active layer BAL3, a third P-type base semiconductor layer PBSC3, a third reflective layer RFL3, and a 3-2-th bonding layer BDL3-2.

Thereafter, the second light-emitting-element layer LDL2 and the third epitaxial wafer substrate EPW3 may be coupled to each other in a way such that the 3-1-th bonding layer BDL3-1 and the 3-2-th bonding layer BDL3-2 face each other. Accordingly, the 3-1-th bonding layer BDL3-1 and the 3-2-th bonding layer BDL3-2 may be coupled to each other, thereby forming a double-layered third bonding layer BDL3.

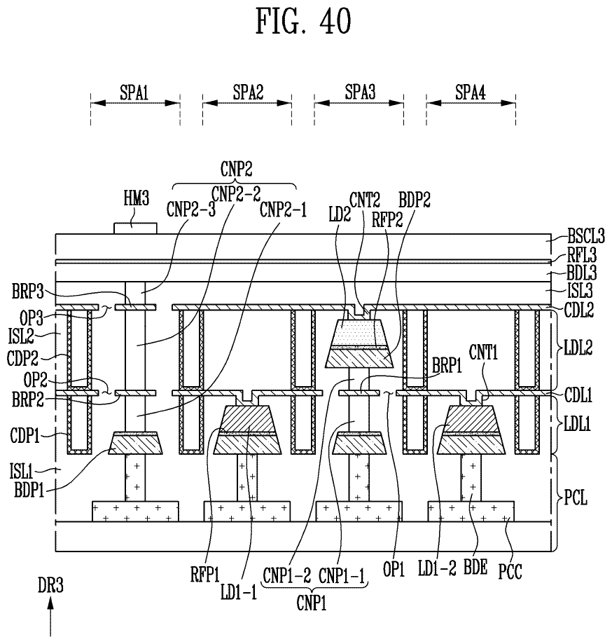

Referring to FIG. 40, a third base semiconductor layer BSCL3 may be formed by removing portions of the third silicon wafer SW3 and the third N-type base semiconductor layer NBSC3 from the third epitaxial wafer substrate EPW3. The third base semiconductor layer BSCL3 may include the third P-type base semiconductor layer PBSC3, the third base active layer BAL3, and the third N-type base semiconductor layer NBSC3.

A third hard mask pattern HM3 may be formed on the third base semiconductor layer BSCL3. The third hard mask pattern HM3 may be formed of a same material as the third insulating layer ISL3. In an embodiment, the third hard mask pattern HM3 may include or be formed of oxide.

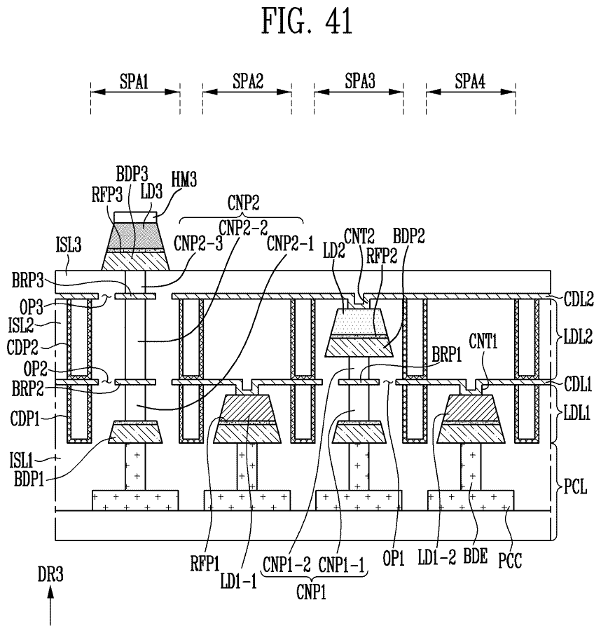

Referring to FIG. 41, the third base semiconductor layer BSCL3, the third reflective layer RFL3, and the third bonding layer BDL3 may be patterned using the third hard mask pattern HM3. Therefore, the third light emitting element LD3, the third reflective pattern RFP3, and the third bonding pattern BDP3, which overlap the first sub-pixel area SPA1, may be formed.

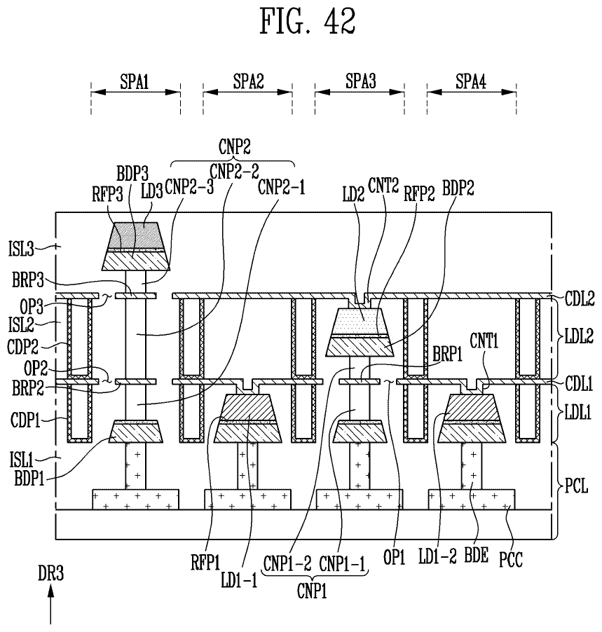

Referring to FIG. 42, the third insulating layer ISL3 may be further formed to cover the third bonding pattern BDP3, the third reflective pattern RFP3, and the third light emitting element LD3. Since the third hard mask pattern HM3 is formed using the same material as the third insulating layer ISL3, the third hard mask pattern HM3 may be included in the third insulating layer ISL3 without being removed.

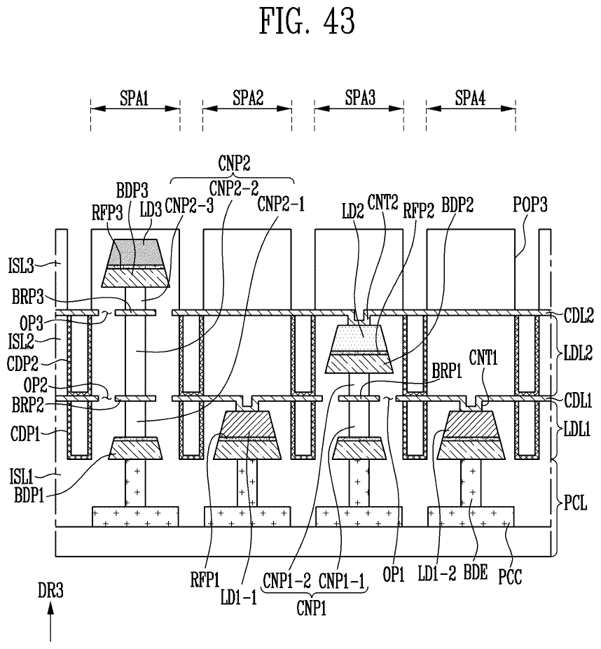

Referring to FIG. 43, third pattern openings POP3 may be formed in the third insulating layer ISL3 disposed on the second conductive layer CDL2. The third pattern openings POP3 may be formed between the first to fourth sub-pixel areas SPA1, SPA2, SPA3, and SPA4. Therefore, the third pattern openings POP3 may be spaced apart from the third bonding pattern BDP3, the third reflective pattern RFP3, and the third light emitting element LD3.

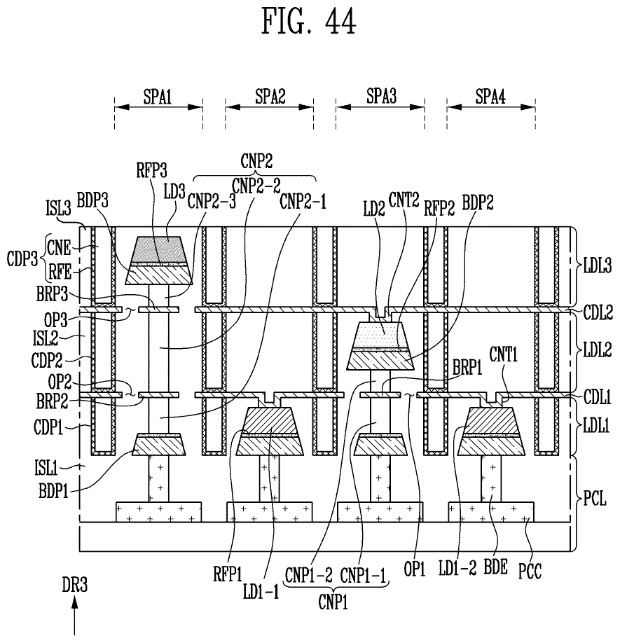

Referring to FIG. 44, the reflective electrode RFE may be formed in each of the third pattern openings POP3. Furthermore, the connection electrode CNE may be formed in each of the third pattern openings POP3 by filling an internal space of the reflective electrode RFE therewith. The reflective electrode RFE and the connection electrode CNE may be formed in each of the third pattern openings POP3, and the upper surface may be planarized through a CMP process. As a result, the third conductive patterns CDP3 may be respectively formed in the third pattern openings POP3.

The third light-emitting-element layer LDL3 including the third bonding pattern BDP3, the third reflective pattern RFP3, the third light emitting element LD3, and the second conductive patterns CDP2 may be formed through the above-described processes.

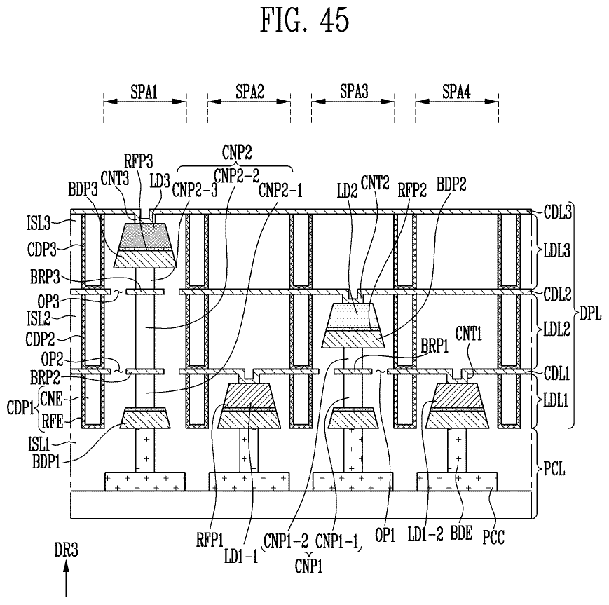

Referring to FIG. 45, the third contact hole CNT3, exposing the third light emitting element LD3, may be formed in the third insulating layer ISL3 on the third light emitting element LD3.

The third conductive layer CDL3 may be formed on the third light emitting element layer LDL3. The third conductive layer CDL3 may contact the third light emitting element LD3 through the third contact hole CNT3. Furthermore, the third conductive layer CDL3 may also contact the third conductive patterns CDP3 and may cover the upper surface of each of the third conductive patterns CDP3.

Furthermore, the third conductive layer CDL3 may extend across the entire area of the display panel.

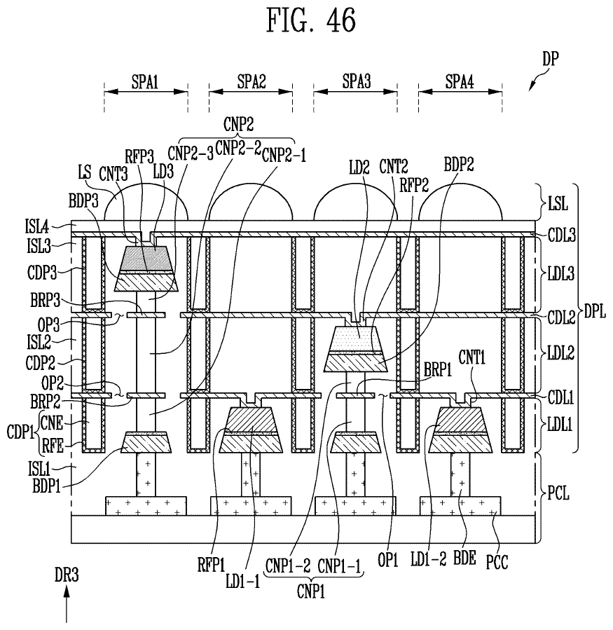

Referring to FIG. 46, a fourth insulating layer ISL4 may be formed on the third conductive layer CDL3. The lens layer LSL may be formed on the fourth insulating layer ISL. The lens layer LSL may include lenses LS formed respectively in the first to fourth sub-pixel areas SPA1, SPA2, SPA3, and SPA4.

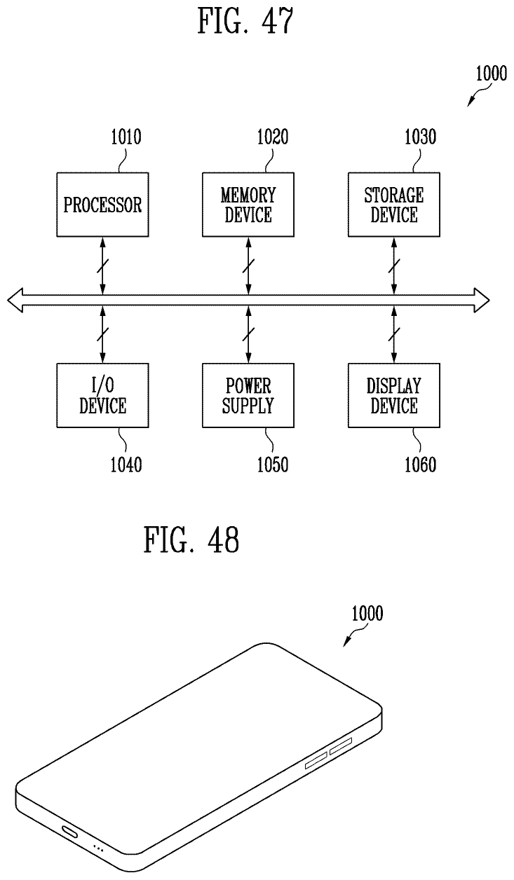

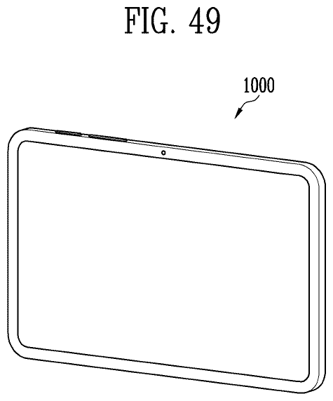

FIG. 47 is a schematic block diagram illustrating an electronic device 1000 including a display device in accordance with an embodiment. FIG. 48 is a schematic diagram illustrating an embodiment where the electronic device 1000 of FIG. 47 is a smartphone. FIG. 49 is a schematic diagram illustrating an embodiment where the electronic device 1000 of FIG. 47 is a tablet computer.

Referring to FIGS. 47 to 49, an embodiment of the electronic device 1000 may include a processor 1010, a memory device 1020, a storage device 1030, an input/output (I/O) device 1040, a power supply 1050, and a display device 1060. The display device 1060 may be the display device DD of FIG. 1. The electronic device 1000 may further include various ports for communication with a video card, a sound card, a memory card, a USB device, or other systems. In an embodiment, as illustrated in FIG. 48, the electronic device 1000 may be a smartphone. In an embodiment, as illustrated in FIG. 49, the electronic device 1000 may be a tablet computer. However, the aforementioned examples are illustrative, and the electronic device 1000 is not necessarily limited to the aforementioned examples. In an embodiment, for example, the electronic device 1000 may be a cellular phone, a video phone, a smart pad, a smartwatch, a navigation device for vehicles, a computer monitor, a laptop computer, a head-mounted display device, or the like.

The processor 1010 may perform specific calculations or tasks. In an embodiment, the processor 1010 may include at least one of a central processing unit, an application processor, a graphic processing unit, a communication processor, an image signal processor, a controller, or the like. The processor 1010 may be connected to other components through an address bus, a control bus, a data bus, and the like. In an embodiment, the processor 1010 may be connected to an expansion bus such as a peripheral component interconnect (PCI) bus. In an embodiment, the processor 1010 may provide input image data to the display device 1060. Hence, the display device 1060 may display an image based on the input image data provided from the processor 1010.

The memory device 1020 may store data to perform the operation of the electronic device 1000. The memory device 1020 may function as a working memory and/or a buffer memory for the processor 1010. In an embodiment, for example, the memory device 1020 may include one or more volatile memory devices such as a dynamic random access memory (DRAM) device, a static random access memory (SRAM) device, and a mobile DRAM device.

The storage device 1030 may store data in response to control signals or data from the processor 1010. The storage device 1030 may include one or more non-volatile storages to retain the data even when the electronic device 1000 is powered off. In some embodiments, the storage device 1030 may include a solid state drive (SSD), a hard disk drive (HDD), a CD-ROM, or the like.

The I/O device 1040 may include input devices such as a keyboard, a keypad, a touchpad, a touch screen, and a mouse, and output devices such as a speaker and a printer. In an embodiment, the display device 1060 may be integrated with the I/O device 1040.

The power supply 1050 may supply power needed to perform the operation of the electronic device 1000. In an embodiment, for example, the power supply 1050 may include a power management integrated circuit (PMIC). In an embodiment, the power supply 1050 may supply power to the display device 1060.

The display device 1060 may display images in response to image data signals and/or control signals from the processor 1010. The display device 1060 may be connected to other components through the buses or other communication links.

According to embodiments described above, a display device may include first to third light-emitting-element layers including respectively light emitting elements configured to generate light of different colors, and each of the first to third light-emitting-element layers further includes conductive patterns in a mesh structure that are arranged in the entire area of a display panel and are connected to each other. Accordingly, a voltage drop (IR Drop) phenomenon in which a voltage drops due to resistance as approaching a central portion of a display area may be reduced. As a result, the contact resistance may also be minimized.

Furthermore, since each of the conductive patterns includes a reflective electrode on a side surface thereof, light generated from the light emitting elements may be reflected by the reflective electrode to be emitted through a display surface of the display device. Hence, the light output efficiency of the display device may be enhanced.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device, comprising:
a pixel circuit layer including a pixel circuit;
a first light-emitting-element layer disposed on the pixel circuit layer, wherein first light-emitting-element layer includes a first light emitting element which generates light of a first color, and first conductive patterns spaced apart from the first light emitting element in a plan view;
a second light-emitting-element layer disposed on the first light-emitting-element layer, wherein second light-emitting-element layer includes a second light emitting element which generates light of a second color different from the first color and is spaced apart from the first light emitting element in the plan view, and second conductive patterns connected to the first conductive patterns; and
a third light-emitting-element layer disposed on the second light-emitting-element layer, wherein third light-emitting-element layer includes a third light emitting element which generates light of a third color different from the first color and the second color and is spaced apart from the first light emitting element and the second light emitting element in the plan view, and third conductive patterns connected to the second conductive patterns.

2. The display device according to claim 1,
wherein each of the first conductive patterns is disposed between the first to the third light emitting elements without overlapping the first to the third light emitting elements in the plan view,
wherein the second conductive patterns respectively overlap the first conductive patterns in the plan view, and
wherein the third conductive patterns respectively overlap the second conductive patterns in the plan view.

3. The display device according to claim 1, wherein each of the first to the third conductive patterns comprises:
a connection electrode; and
a reflective electrode covering at least a portion of the connection electrode.

4. The display device according to claim 3, wherein the reflective electrode covers a side surface of the connection electrode.

5. The display device according to claim 3,
wherein the connection electrode includes at least one selected from copper and tungsten, and
wherein the reflective electrode includes at least one selected from aluminum and silver.

6. The display device according to claim 1, further comprising:
a first conductive layer disposed between the first light-emitting-element layer and the second light-emitting-element layer;
a second conductive layer disposed between the second light-emitting-element layer and the third light-emitting-element layer; and
a third conductive layer disposed on the third light-emitting-element layer.

7. The display device according to claim 6,
wherein the first conductive layer contacts the first light emitting element, the first conductive patterns, and the second conductive patterns,
wherein the second conductive layer contacts the second light emitting element, the second conductive patterns, and the third conductive patterns, and
wherein the third conductive layer contacts the third light emitting element and the third conductive patterns.

8. The display device according to claim 6, wherein each of the first to the third conductive layers includes indium tin oxide (ITO).

9. The display device according to claim 6, further comprising:
a first connection pattern overlapping the second light emitting element, and connecting the pixel circuit layer to the second light emitting element; and
a second connection pattern overlapping the third light emitting element, and connecting the pixel circuit layer to the third light emitting element.

10. The display device according to claim 9, wherein each of the first connection pattern and the second connection pattern includes at least one selected from copper and tungsten.

11. The display device according to claim 9, wherein the first conductive layer comprises:
a first bridge pattern overlapping the second light emitting element, and contacting the first connection pattern; and
a second bridge pattern overlapping the third light emitting element, and contacting the second connection pattern,
wherein a first opening is defined in the first conductive layer around the first bridge pattern; and
wherein a second opening is defined in the first conductive layer around the second bridge pattern.

12. The display device according to claim 11, wherein the second conductive layer comprises:
a third bridge pattern overlapping the third light emitting element, and contacting the second connection pattern,
wherein a third opening is defined in the second conductive layer around the third bridge pattern.

13. The display device according to claim 9, wherein the first light-emitting-element layer further comprises first bonding patterns connected to the pixel circuit layer, the first light emitting element, the first connection pattern, and the second connection pattern.

14. The display device according to claim 13, wherein the second light-emitting-element layer further comprises a second bonding pattern connected to the first connection pattern and the second light emitting element.

15. The display device according to claim 14, wherein the third light-emitting-element layer further comprises a third bonding pattern connected to the second connection pattern and the third light emitting element.

16. The display device according to claim 1, further comprising:
a lens layer disposed on the third light-emitting-element layer, wherein lens layer includes lenses overlapping respectively the first to the third light emitting elements.

17. A display device including first to fourth sub-pixel areas, the display device comprising:
a pixel circuit layer including a pixel circuit;
first to fourth sub-pixels respectively disposed in the first to fourth sub-pixel areas;
a first light-emitting-element layer disposed on the pixel circuit layer, wherein the first light-emitting-element layer includes a first first light emitting element disposed in the second sub-pixel area, a first second light emitting element disposed in the fourth sub-pixel area, and first conductive patterns disposed between the first to fourth sub-pixel areas;
a second light-emitting-element layer disposed on the first light-emitting-element layer, wherein the second light-emitting-element layer includes a second light emitting element disposed in the third sub-pixel area, and second conductive patterns disposed between the first to fourth sub-pixel areas, and overlapping respectively the first conductive patterns; and
a third light-emitting-element layer disposed on the second light-emitting-element layer, wherein the third light-emitting-element layer includes a third light emitting element disposed in the first sub-pixel area, and third conductive patterns disposed between the first to fourth sub-pixel areas, and overlapping respectively the first and the second conductive patterns.

18. The display device according to claim 17, further comprising:
a first conductive layer disposed between the first light-emitting-element layer and the second light-emitting-element layer, and connected to the first first light emitting element, the first second light emitting element, the first conductive patterns, and the second conductive patterns;
a second conductive layer disposed between the second light-emitting-element layer and the third light-emitting-element layer, and connected to the second light emitting element, the second conductive patterns, and the third conductive patterns; and
a third conductive layer disposed on the third light-emitting-element layer, and connected to the third light emitting element and the third conductive patterns.

19. The display device according to claim 18,
wherein the first light-emitting-element layer further includes a first first connection pattern overlapping the third sub-pixel area,
wherein the second light-emitting-element layer further includes a first second connection pattern overlapping the third sub-pixel area, and connected to the first first connection pattern and the second light emitting element, and
wherein the first first connection pattern and the first second connection pattern are connected to each other through the first conductive layer.

20. The display device according to claim 19,
wherein the first light-emitting-element layer further includes a second first connection pattern overlapping the first sub-pixel area,
wherein the second light-emitting-element layer further includes a second second connection pattern overlapping the first sub-pixel area, and connected to the second first connection pattern,
wherein the third light-emitting-element layer further includes a second third connection pattern overlapping the first sub-pixel area, and connected to the second second connection pattern and the third light emitting element,
wherein the second first connection pattern and the second second connection pattern are connected to each other through the first conductive layer, and
wherein the second second connection pattern and the second third connection pattern are connected to each other through the second conductive layer.

21. An electronic device, comprising:
a processor which provides input image data; and
a display device which displays an image based on the input image data,
wherein the display device comprises:
a pixel circuit layer including a pixel circuit;
a first light-emitting-element layer disposed on the pixel circuit layer, wherein the first light-emitting-element layer includes a first light emitting element which generates light of a first color, and first conductive patterns spaced apart from the first light emitting element in a plan view;
a second light-emitting-element layer disposed on the first light-emitting-element layer, wherein the second light-emitting-element layer includes a second light emitting element which generates light of a second color different from the first color and is spaced apart from the first light emitting element in the plan view, and second conductive patterns connected to the first conductive patterns; and
a third light-emitting-element layer disposed on the second light-emitting-element layer, wherein the third light-emitting-element layer includes a third light emitting element which generates light of a third color different from the first color and the second color and is spaced apart from the first light emitting element and the second light emitting element in the plan view, and third conductive patterns connected to the second conductive patterns.
